(19) United States
(12) Patent Application Publication
(10) Pub. No.: US 2007/0218680 A1
(43) Pub. Date: Sep. 20, 2007

(54) Method for fabricating semiconductor device and method for fabricating magnetic head

(75) Inventors: Tsukasa Itani, Kawasaki (JP); Makoto Sasaki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/475,163

(22) Filed: Jun. 27, 2006

(30) Foreign Application Priority Data
Mar. 20, 2006 (JP) 2006-076491

(51) Int. Cl. H01L 21/4763; H01L 21/302

(52) U.S. Cl. 438/638; 257/E21.577; 257/E21.224; 438/745

(57) ABSTRACT

The method for fabricating a semiconductor device comprises the step of forming an interconnection trench 38 in an inter-layer insulation film 34, the step of forming an interconnection layer 44 of Cu as the main material in the interconnection trench 38, and the step of performing cloth-rubbing processing of rubbing a cloth 2 containing pure water with ammonia and hydrogen solved in on the surface of the interconnection layer 44 buried in the interconnection trench 38.

### CROSS-REFERENCE TO RELATED APPLICATIONS

This application is based upon and claims the benefit of priority from the prior Japanese Patent Application No. 2006-076491, filed on Mar. 20, 2006, the entire contents of which are incorporated herein by reference.

### BACKGROUND OF THE INVENTION

The present invention relates to a method for fabricating a semiconductor device having an interconnection structure using copper as a main material of the interconnection layer, and a method for fabricating a magnetic head having an interconnection structure using copper as a main material of the interconnection layer.

As semiconductor devices have been larger scaled and higher integrated, the design rule of the interconnections has been reduced with the generations. Conventionally, the interconnection layers have been formed by depositing interconnection materials and patterning the deposited interconnection materials using lithography and dry etching, but technical limitations in this process commences to arise as the generation has advanced. As a new process for forming the interconnection layers, which takes over the conventional interconnection forming process, the process, the so-called damascene process, of forming a trench pattern and a hole pattern in an inter-layer insulation film and burying an interconnection material in the trench and the hole, is being used. With the shift in the interconnection forming process, copper (Cu), which has specific resistance lower than aluminum (Al) conventionally used as the interconnection material and has superior electro-migration resistance, has come into use.

Semiconductor devices of the multilayer interconnection structure including semiconductor elements, such as transistors, etc., highly integrated by such interconnection forming process are being rapidly developed. Coupled with this, a number of methods for improving the reliability of the semiconductor devices by suppressing the electro-migration in the interconnection layers, etc. have been reported (see, e.g., Japanese published unexamined patent application No. 2000-323476 (Patent Reference 1), Japanese published unexamined patent application No. 2002-246391 (Patent Reference 2) and Japanese published unexamined patent application No. 2003-142580 (Patent Reference 3)).

In operation of a semiconductor device, the device itself generates heat, and its temperature rises. It has been conventionally known that when the multilayer interconnection structure is exposed to high temperature environment due to such temperature rise in operation and the processes following the formation of the multilayer interconnection structure, etc., Cu atoms in the interconnection layers and pores formed in the interconnection layers migrate, forming large voids in the interconnection layers, and these voids causes conduction defects of the interconnection layers.

In the generation where widths of the interconnection layers are 1 μm or more, the widths of the interconnection layers are large enough for sizes of the voids generated in the interconnection layers. Accordingly, the conduction defects due to the voids did not much affect the operation characteristics and reliability of semiconductor devices.

However, in the generation where widths of the interconnection layers are 0.5 μm or less, the influences of the interconnection resistance increase due to voids generated in the interconnection layers on the operation characteristics and reliability of semiconductor devices become unignorable. Especially in forming hereafter fine interconnection layers of 0.2 μm or less width, it is essential to suppress the generation of conduction defects due to the voids.

Patent References 1 to 3 described above disclose the method for improving the reliability of semiconductor devices. The methods improve the reliability by improving the resistance to the electro-migration in the interconnection layers. So far, sufficient countermeasures to the conduction defects of the interconnection layers due to the voids caused by heat have not been made.

As such a countermeasure, the applicant of the present application has proposed the method of concurrently spraying nitrogen gas and water on the surface of an interconnection layer to thereby suppress the generation of voids due to heat to improve the reliability of semiconductor devices (see Japanese published unexamined patent application No. 2005-183814 (Patent Reference 4)).

In the magnetic heads of magnetic recording devices, such as hard discs, etc. as well, the interconnection layers forming a coil for generating writing magnetic fields are increasingly fined. The minimum interconnection width of such interconnection layers has become below 1 μm. Accordingly, as in the case of the semiconductor device described above, countermeasures to the conduction defect due to the voids generated by heat must be made in the interconnection layers of the magnetic head.

The related arts are also disclosed in, e.g., Japanese Patent No. 3003684 (Patent Reference 5).

### SUMMARY OF THE INVENTION

An object of the present invention is to provide a method for fabricating a semiconductor device which suppresses the generation of voids in the interconnection layers in high temperature environments to thereby suppress the conduction defects of the interconnection layers, and improves the reliability of the semiconductor device.

Another object of the present invention is to provide a method for fabricating a magnetic head which suppresses the generation of voids in the interconnection layers in high temperature environments to thereby suppress the conduction defects of the interconnection layers, and improves the reliability of the magnetic head.

According to one aspect of the present invention, there is provided a method for fabricating a semiconductor device comprising the steps of: forming an opening in an insulation film; forming an interconnection layer of Cu as a main material in the opening; and performing cloth-rubbing processing of rubbing a cloth containing pure water with ammonia and hydrogen solved in on a surface of the interconnection layer buried in the opening.

According to another aspect of the present invention, there is provided a method for fabricating a magnetic head comprising the steps of: forming an opening of a pattern of a coil in an insulation film; forming an interconnection layer formed of Cu as a main material and forming a coil in the opening; and performing cloth-rubbing processing of rubbing a cloth containing pure water with ammonia and hydrogen solved in on a surface of the interconnection layer buried in the opening.

The method for fabricating a semiconductor device according to the present invention comprises the steps of: forming an opening in an insulation film; forming an interconnection layer of Cu as a main material in the opening; and performing cloth-rubbing processing of rubbing a cloth containing pure water with ammonia and hydrogen solved in on a surface of the interconnection layer buried in the opening, whereby the migration of the Cu atoms of the interconnection layer in a high temperature environment is suppressed, and the generation rate of conduction defects of the interconnection layer can be decreased. Thus, the semiconductor devices having multilayer interconnection layers of good stress-migration resistance and high reliability can be provided.

The method for fabricating a magnetic head according to the present invention comprises the steps of: forming an opening of a pattern of a coil in an insulation film; forming an interconnection layer formed of Cu as a main material and forming a coil in the opening; and performing cloth-rubbing processing of rubbing a cloth containing pure water with ammonia and hydrogen solved in on a surface of the interconnection layer buried in the opening, whereby the migration of the Cu atoms of the interconnection layer in a high temperature environment is suppressed, and the generation rate of conduction defects of the interconnection layer forming the coil can be decreased. Thus, the magnetic heads having multilayer interconnection layers of high reliability can be provided.

### BRIEF DESCRIPTION OF THE DRAWINGS

FIG. 1 is a diagrammatic sectional view explaining the cloth-rubbing processing of the present invention.

FIGS. 2A and 2B are XPS spectra of changes of the oxidation state of the Cu of the interconnection layer subjected to the cloth-rubbing processing of the present invention.

FIG. 3 is a graph of results of the secondary ion mass spectroscopic analysis of the surface after a diffusion preventing film has been formed on an interconnection layer.

FIG. 4 is a graph of results of the measurement of surface roughness of diffusion preventing films formed on interconnection layers.

FIGS. 5A-5D, 6A-6C, 7A-7B, 8A-8B, 9A-9B, 10A-10B, 11A-11B, 12A-12C, 13 and 14A-14B are sectional views of the semiconductor device in the steps of the method for fabricating the same according to a first embodiment of the present invention, which show the method.

FIG. 15 is a perspective of a magnetic head, which illustrates a structure thereof.

FIGS. 16A-16C, 17A-17B, 18A-18B, 19A-19B and 20A-20B are sectional views of the magnetic head in the steps of the method for fabricating the same according to a second embodiment of the present invention, which show the method.

### DETAILED DESCRIPTION OF THE INVENTION

### Principle of the Present Invention

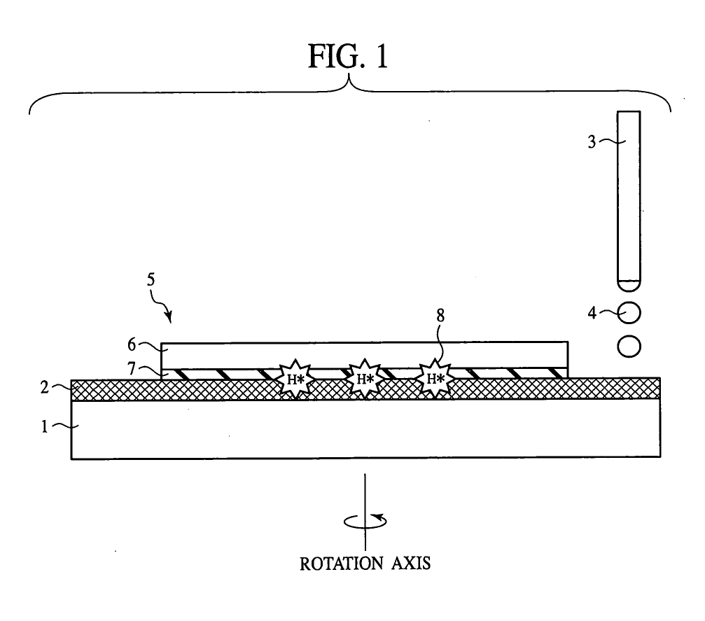

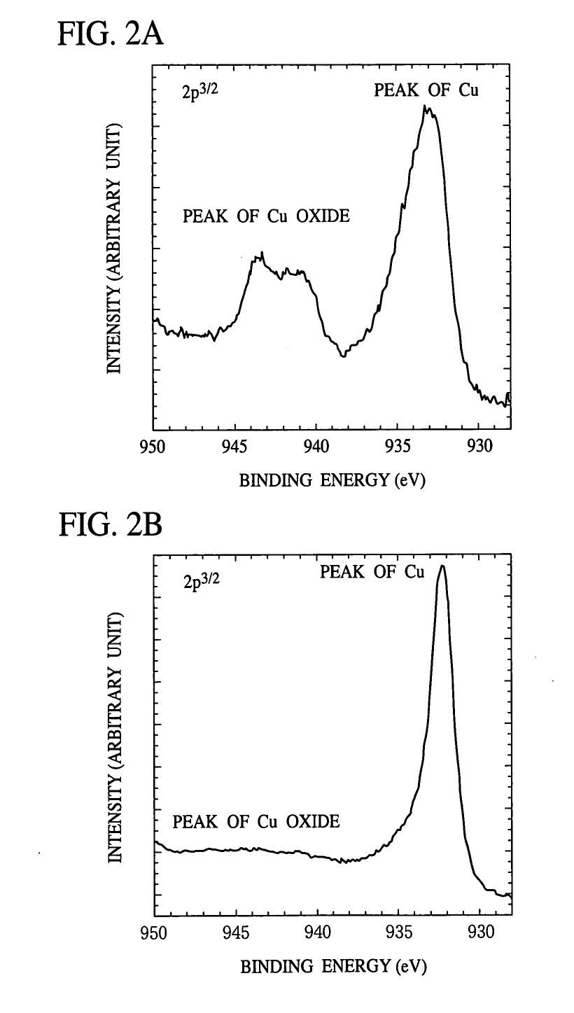

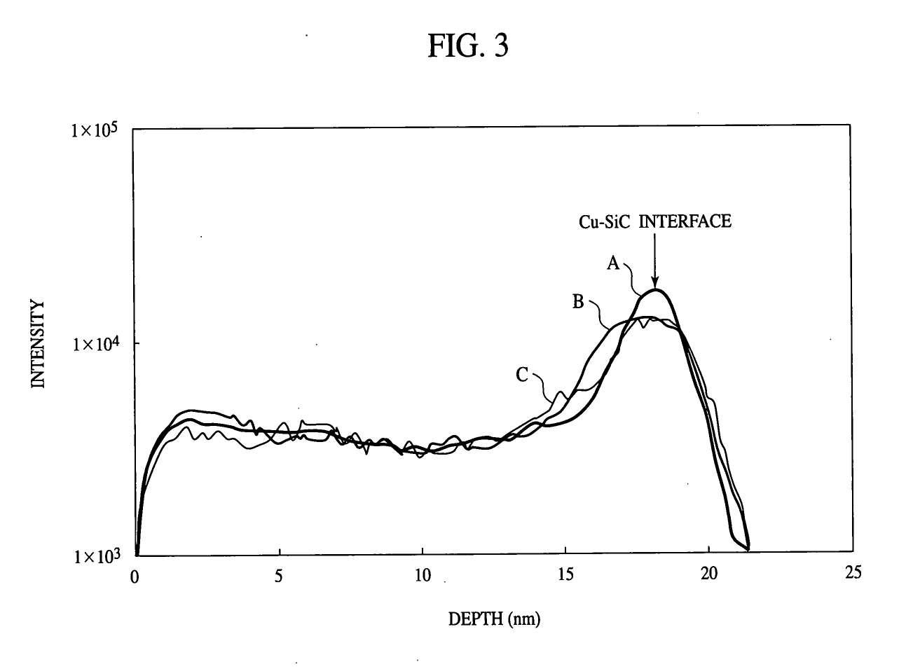

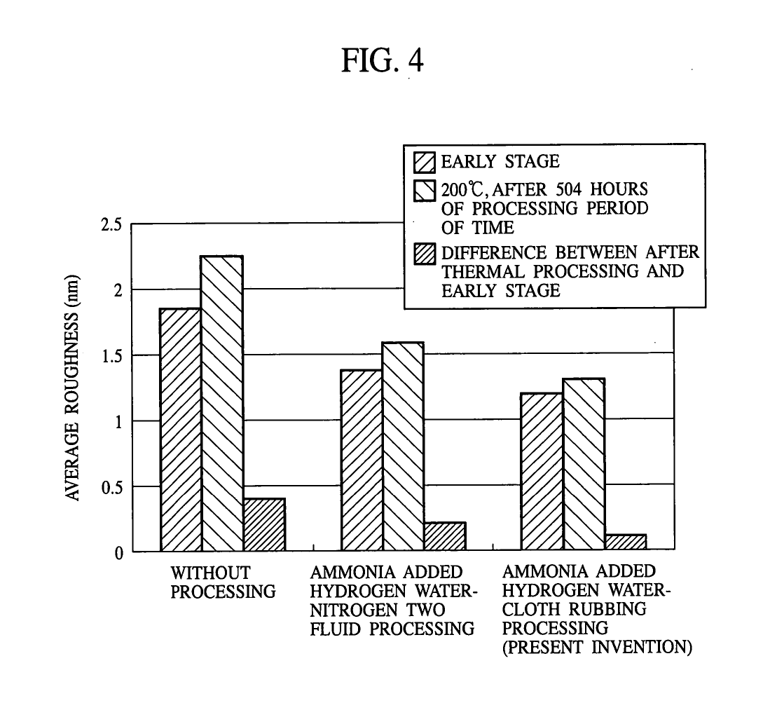

First, the principle of the present invention will be explained with reference to FIGS. 1 to 4. FIG. 1 is a diagrammatic sectional view explaining the cloth-rubbing processing of the present invention. FIGS. 2A and 2B are XPS spectra of changes of the oxidation state of the Cu of the interconnection layer subjected to the cloth-rubbing processing of the present invention. FIG. 3 is a graph of results of the secondary ion mass spectroscopic analysis of the surface after a diffusion preventing film has been formed on an interconnection layer. FIG. 4 is a graph of results of the measurement of surface roughness of diffusion preventing films formed on interconnection layers.

The method for fabricating a semiconductor device according to the present invention is characterized mainly by comprising the step of forming an opening in an insulation film, the step of forming an interconnection layer formed of Cu as a main material in the opening, and the step of performing cloth-rubbing processing of rubbing a surface of the interconnection layer buried in the opening with a cloth containing pure water with ammonia and hydrogen solved in.

Similarly, the method for fabricating a magnetic head according to the present invention is characterized mainly by comprising the step of forming an opening of a coil pattern in an insulation film, the step of forming an interconnection layer formed of Cu as a main material in the opening which forms a coil, and the step of performing cloth-rubbing processing of rubbing a surface of the interconnection layer buried in the opening with a cloth containing pure water with ammonia and hydrogen solved in.

The surface of an interconnection layer of Cu as the main material exposed after flattening by CMP (Chemical Mechanical Polishing) in the damascene process, is formed of substantially pure Cu, but a little oxide layer is exposed on the outermost surface. Conventionally, immediately after flattening by CMP, the diffusion preventing film of SiC or others for preventing the diffusion of Cu which is the interconnection layer material has been formed. When a multilayer interconnection formed by such a conventional step is exposed to high temperature environment, Cu atoms of the interconnection material and pores in the interconnection layer migrate and resultantly voids generate in the interconnection layer. Such voids are one of the causes for the conduction defect of the interconnection layer.

The applicant of the present application proposes as a method for suppressing the generation of the conduction defect due to such voids, the method for fabricating a semiconductor device including the step of performing nitrogen-two-fluid processing in which after an interconnection layer is buried in an interconnection trench in an inter-layer insulation film and is planarized by CMP and before a diffusion preventing film for preventing the diffusion of Cu as the interconnection material is formed, nitrogen gas and water are concurrently sprayed on the surface of the interconnection layer (see Patent Reference 4). In the nitrogen-two-fluid processing disclosed in Patent Reference 4, pure water, carbonated water with carbonic acid dissolved in pure water, etc. are sprayed on the surface of the interconnection layer concurrently with nitrogen gas.

The inventors of the present application have found that pure water with ammonia and hydrogen solved in is used as the water to be blown concurrently with nitrogen gas in the step of nitrogen-two-fluid processing, whereby the generation ratio of the conduction defect of the interconnection layer can be much decreased. In the specification of the present application, the pure water with ammonia and hydrogen dissolved in is suitably called “ammonia added hydrogen water”.

Furthermore, the inventors of the present application have found that the ratio of generating the conduction defect is further lowered even when the multilayer interconnection is exposed to a high temperature environment by performing the cloth-rubbing processing of rubbing a cloth containing ammonia added hydrogen water on the surface of an interconnection layer after the interconnection layer is buried in an interconnection trench in an inter-layer insulation film and is planarized by CMP and before a diffusion preventing film for preventing the diffusion of Cu as the interconnection material is formed. Additionally, the inventors of the present application have found that the ratio of generating the conduction defect is further lowered when the cloth-rubbing processing of rubbing a cloth containing the ammonia added hydrogen water is performed than when the nitrogen-two-fluid processing is performed.

The cloth-rubbing processing of the present invention will be explained with reference to FIG. 1.

For the cloth-rubbing processing of the present invention, i.e., cloth polish processing, the general polishing apparatus can be used. For example, a CMP (Chemical Mechanical Polishing) apparatus or others can be used.

The polishing apparatus used in the cloth-rubbing processing includes a cloth 2 which is to contain the ammonia added hydrogen water disposed on a polish table 1 which is disposed rotatable on a rotation axis, as illustrated. A nozzle 3 for dropping the ammonia added hydrogen water on the cloth 2 is disposed above the polish table 1 with the cloth 2 disposed on.

The cloth-rubbing processing is performed on an object-to-be-processed 5, an interconnection layer formed of Cu as the main material with such polishing apparatus. The object-to-be-processed 5 includes an insulation film 7 formed on a substrate 6. The interconnection layer formed of Cu as the main material is buried in the insulation film 7. The surface of the interconnection layer is exposed on the surface of the insulation film 7.

In the cloth-rubbing processing, while the ammonia added hydrogen water 4 is being fed onto the cloth 2 from the nozzle 3, the polish table 1 is rotated with the surface-to-be-processed of the object-to-be-processed 5 having the surface of the interconnection layer buried in the insulation film 7 exposed kept in press-contact with the cloth 2. Thus, the cloth 2 containing the ammonia added hydrogen water rubs the surface of the interconnection layer formed of Cu as the main material.

The decrease of the ratio of generating the conduction defect by the rubbing processing of the present invention, in which the cloth containing the ammonia added hydrogen water rubs the surface of the interconnection layer formed of Cu as the main material will be due to the same factors as in the nitrogen-two-fluid processing.

As a first factor, the ammonia added hydrogen water will reduce the surface of the exposed Cu layer or prevent the oxidation of the surface of the Cu layer.

As a second factor, with the cloth-rubbing processing using the ammonia added hydrogen water, the nitrogen quantity in the surface of the Cu layer will be increased.

Furthermore, as a third factor, the ammonia added hydrogen water will clean the surface of the exposed Cu layer and remove dusts from the surface.

The present invention has, in addition to the above-described factors, the mechanical factor that the surface of the interconnection layer is rubbed against the cloth. Thus, the first to the third factors more contribute to the decrease of generating the conduction defect in comparison with the nitrogen-two-fluid processing. Consequently, the present invention will be able to more effectively decrease the generation of the conduction defect.

For example, in the cloth-rubbing processing, as illustrated in FIG. 1, hydrogen radicals 8 will be generated at the contact surface between the surface-to-be-processed of the object-to-be-processed 5 and the cloth 2 by the friction between both. The hydrogen radicals 8 will enhance the reduction of the exposed surface of the Cu layer and the prevention of the oxidation of the surface of the Cu layer.

FIGS. 2A and 2B shows the result of measuring by XPS (X-ray Photoelectron Spectroscopy) the oxidation states before and after the cloth-rubbing processing using the ammonia added hydrogen water regarding the surface of the Cu layer of a sample having the Cu layer planarized by CMP, rinsed and left in the atmospheric air for 10 hours. FIG. 2A is the XPS spectrum before the cloth-rubbing processing using the ammonia added hydrogen water, and FIG. 2B is the XPS spectrum after the cloth-rubbing processing using the ammonia added hydrogen water.

Before the cloth-rubbing processing, as shown in FIG. 2A, the peak of the Cu and the peak of the oxide of the Cu are observed. However, after the cloth-rubbing processing, as illustrated in FIG. 2B, the peak of the oxide of the Cu has substantially disappeared.

Based on the results of the measurements by the XPS shown in FIGS. 2A and 2B, it is seen that the cloth-rubbing processing using the ammonia added hydrogen water reduces and removes the oxide layer on the surface of the Cu layer.

FIG. 3 is a graph of results of the secondary ion mass spectroscopic analysis of the vicinity of the surface of the semiconductor device after an SiC film as a diffusion preventing film has been formed on an inter-layer insulation film with an interconnection layer buried in which has been formed of Cu as the main material by the damascene process. In FIG. 3, the depth profile A indicates the result of the case that an interconnection layer was formed, the cloth-rubbing processing using the ammonia added hydrogen water and the nitrogen-two-fluid processing of concurrently spraying ammonia added hydrogen water and nitrogen gas were sequentially performed, and then an SiC film was formed on an inter-layer insulation film with the interconnection layer buried in. The depth profile B indicates the result of the case that an interconnection layer was formed, the nitrogen-two-fluid processing of concurrently spraying ammonia added hydrogen water and nitrogen gas was performed without the cloth-rubbing processing, and then an SiC film was formed on an inter-layer insulation film with the interconnection layer buried in. The depth profile C indicates the result of the case that an interconnection layer was formed, and then an SiC film was immediately formed on an inter-layer insulation film with the interconnection layer buried in without the cloth-rubbing processing and the nitrogen-two fluids processing.

The analysis results by the secondary ion mass spectroscopy shown in FIG. 3 show that in the case (Graph B) where the nitrogen-two-fluid processing was performed without the cloth-rubbing processing, the quantity of nitrogen present near the interface between the interconnection layer of Cu as the main material and the SiC film is increased although a little in comparison with that of the case without any processing (Graph C). Furthermore, it is found that in the case (Graph A) with the cloth-rubbing processing, the quantity of nitrogen present near the interface between the interconnection layer and the SiC film is further increased in comparison with those of the case without the cloth-rubbing processing but with the nitrogen-two-fluid processing (Graph B) and the case without any processing (Graph C).

These results show that nitrogen is adsorbed onto or exists in forms of compounds on the surface of the Cu layer by performing the nitrogen-two-fluid processing and cloth-rubbing processing using the ammonia added hydrogen water, and the nitrogen quantity is increased by performing the cloth-rubbing processing using ammonia added hydrogen water.

The adsorption of the nitrogen onto the surface of an interconnection layer of Cu as the main material will depress the generation ratio of the conduction defect of the interconnection layer even when exposed to a high temperature environment by the following mechanism. That is, when a diffusion preventing film for preventing the diffusion of Cu with nitrogen adsorbed on the surface of the interconnection layer of Cu as the main material is formed, the presence of the nitrogen makes it difficult for the Cu atoms of the interconnection layer to migrate in a high temperature environment. Resultantly, the generation of voids in the interconnection layer is suppressed, the generation ratio of the conduction defect of the interconnection layer is suppressed low, and the stress-migration resistance of the interconnection layer can be improved.

It is confirmed, based on the results of the measurement of the average roughness of the diffusion preventing film formed on the interconnection layer, which are shown in FIG. 4, that the migration of the Cu atoms in the interconnection layer in high temperature environments is suppressed by the cloth-rubbing processing using ammonia added hydrogen water.

FIG. 4 is a graph of the results of measuring the average roughness of the surface of an SiC film formed on an inter-layer insulation film with an interconnection layer buried in by the damascene process. Respectively for the case that the cloth-rubbing processing using ammonia added hydrogen water of the present invention and the nitrogen-two-fluid processing using ammonia added hydrogen water were sequentially performed, the case that the nitrogen-two-fluid processing using ammonia added hydrogen water was performed without the cloth-rubbing processing and the case that the cloth-rubbing processing and the nitrogen-two-fluid processing were not performed, the average surface roughness of an SiC film immediately after deposited and an SiC film left at 200° C. for 504 hours after deposited was measured. The average surface roughness was measured with an atomic force microscope. For each case, the change quantity of the average roughness was given by subtracting average roughness of the surface of the SiC film immediately after deposited from an average roughness of the surface of the SiC film immediately after thermal processing.

The graph shown in FIG. 4 shows that in the case with the nitrogen-two-fluid processing, the average surface roughness is generally smaller and the change quantity of the average roughness of the surface due to the thermal processing is suppressed smaller in comparison with the case without the cloth-rubbing processing and the nitrogen-two-fluid processing. The graph also shows that the cloth-rubbing processing using the ammonia added hydrogen water makes the average surface roughness generally further smaller and suppresses the change quantity of the average surface roughness due to the thermal processing further smaller.

As described above, the cloth-rubbing processing using the ammonia added hydrogen water suppresses further smaller the change quantity, due to the thermal processing, of the average surface roughness of the diffusion prevention film formed on the interconnection layer. Based on this, the cloth-rubbing processing using the ammonia added hydrogen water will make the migration of the Cu atoms of the interconnection layer due to the thermal processing difficult, and the generation of voids in the interconnection layer will be suppressed.

As described above, according to the present invention, after an interconnection layer of Cu as the main material is buried in an interconnection trench and is planarized by CMP, and before a diffusion prevention film of Cu is formed, the cloth-rubbing processing of rubbing a cloth containing the ammonia added hydrogen water against the surface of the interconnection layer is performed, whereby the migration of the Cu atoms of the interconnection layer in a high-temperature environment is suppressed, and the generation of voids in the interconnection layer can be suppressed.

Thus, the method for fabricating a semiconductor device according to the present invention can provide a semiconductor device having good stress-migration resistance of the interconnection layer and high reliability.

As mentioned above, also in the magnetic heads of magnetic recording devices, such as hard discs, etc., the interconnection layer forming the coil for generating a write-in magnetic field are increasingly fined, and it is a problem to suppress the generation of voids in the interconnection layers.

According to the method for fabricating a magnetic head according to the present invention, the generation of voids in the interconnection layer forming a coil for generating a write-in magnetic field is suppressed, and cam provide a magnetic head of high reliability.

Details of the conditions, etc. of the cloth-rubbing processing using the ammonia added hydrogen water of the present invention are as follows.

The apparatus for rubbing a cloth against the surface of an interconnection layer in the cloth-rubbing processing can be a general polishing apparatus as described above and can be selected suitably corresponding to a required precision etc. of an object-to-be-processed. For example, a CMP apparatus can be used.

The pure water used in the ammonia added hydrogen water to be contained in the cloth in the cloth-rubbing processing may have the purity usable in semiconductor device fabricating processes. For example, the pure water may have, e.g., an above 17.6 MΩ·cm including 17.6 MΩ·cm specific resistance and is of the level of several particles/mL of a 0.5 μm particle diameter excluding 0.5 μm particle diameter.

Ammonia and hydrogen are solved in such pure water to prepare the ammonia added hydrogen water. The ammonia concentration in the ammonia added hydrogen water is set at, e.g., 0.1-5.0 ppm, and the hydrogen concentration is set at, e.g., 0.1-5.0 ppm.

In the cloth-rubbing processing, the flow rate of the ammonia added hydrogen water to be dropped from the nozzle onto the cloth can be set suitably at a required value, e.g., 20-300 mL/min, preferably 50-200 mL/min. This is because when the flow rate is too large, the effect of the rubbing processing can not be sufficient while when the flow rate is too small, patterns may be broken.

A pressing force for pressing the object-to-be-processed on the polish table when the polish table is rotated with the cloth press-contacted to the processing surface of the object-to-be-processed can be suitable set at a required value, e.g., 0.01-0.35 kg/cm², preferably 0.04-0.21 kg/cm². This is because when the pressing force is too small, the effect of the cloth-rubbing processing cannot be sufficient while when the pressing force is too large, patterns may be broken.

The period of time of the cloth-rubbing processing can be set suitably corresponding to various conditions, such as the flow rate of the ammonia added hydrogen water, the pressure to be applied to the object-to-be-processed, etc. and can be set at, e.g., 20-300 seconds.

The cloth-rubbing processing of the present invention may be combined with the nitrogen-two-fluid processing or may be singly performed without being combined with the nitrogen-two-fluid processing. That is, it is possible that an interconnection layer of Cu as the main material is formed, then the cloth-rubbing processing of the present invention and the nitrogen-two-fluid processing are sequentially performed, and then a diffusion prevention film is formed on an inter-layer insulation film with the interconnection layer buried in. The nitrogen-two-fluid processing may be performed before the cloth-rubbing processing of the present invention is performed. It is also possible that the cloth-rubbing processing of the present invention is singly made after an interconnection layer of Cu as the main material has been formed, and without the nitrogen-two-fluid processing, a diffusion prevention film is formed on an inter-layer insulation film with the interconnection layer buried in.

In the nitrogen-two-fluid processing combined with the cloth-rubbing processing of the present invention, the water to be blown concurrently with nitrogen gas can be suitably pure water, carbonated water with carbonic acid dissolved in pure water, hydrogen water with hydrogen solved in pure water, ammonia added hydrogen water or others.

In the above, in the cloth-rubbing processing, a cloth containing the ammonia added hydrogen water rubs the surface of an interconnection layer. However, it is possible that no ammonia is solved in the hydrogen water with hydrogen solved in pure water, and a cloth containing this hydrogen water rubs the surface of an interconnection layer. In this case as well, the surface of the interconnection layer is reduced or is prevented from being oxidized, and the surface of the interconnection layer can be cleaned, whereby the generation of the conduction defect can be prevented.

The hydrogen plasma processing of applying hydrogen plasmas to the surface of an inter-layer insulation film with an interconnection layer buried in may be performed after the above-described cloth-rubbing processing and before the formation of a diffusion preventing film. The hydrogen plasma processing is performed on the surface of the inter-layer insulation film and the surface of the interconnection layer, whereby the surfaces are purified, and the diffusion preventing film can be formed with high adhesion. The reliability of the semiconductor device and the magnetic head including such interconnection structure can be improved.

### A First Embodiment

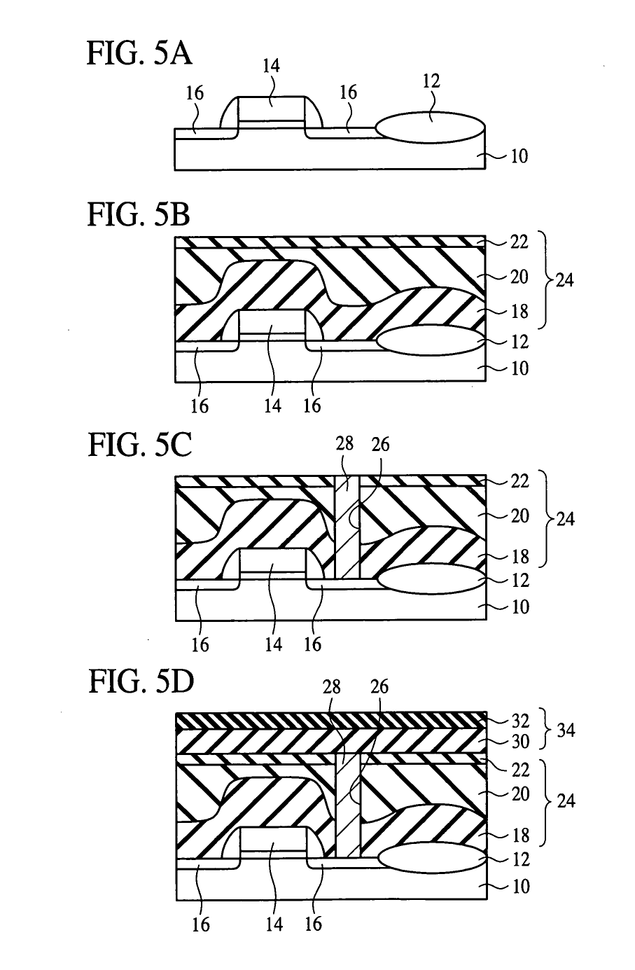

The method for fabricating a semiconductor device according to a first embodiment will be explained with reference to FIGS. 5A-5D, 6A-6C, 7A-7B, 8A-8B, 9A-9B, 10A-10B, 11A-11B, 12A-12B, 13 and 14A-14B. FIGS. 5A-5D, 6A-6C, 7A-7B, 8A-8B, 9A-9B, 10A-10B, 11A-11B, 12A-12B, 13 and 14A-14B are sectional views of the semiconductor device in the steps of the method for fabricating the same according to a first embodiment of the present invention, which show the method.

First, in the same way as in, e.g., the usual MOS transistor fabricating method, a MOS transistor including a gate electrode 14 and a source/drain diffused layers 16 is formed on a silicon substrate 10 with a device isolation film 12 formed on (see FIG. 5A). Various semiconductor devices other than MOS transistors can be fabricated on the semiconductor substrate 10.

Then, a silicon nitride film 18 of, e.g., a 0.1 μm-thickness is formed by, e.g., CVD (Chemical Vapor Deposition) on the silicon substrate 10 with the MOS transistor formed on.

Next, a PSG (Phosphorous Silicate Glass) film 20 of, e.g., a 1.5 μm-thickness is formed on the silicon nitride film 18 by, e.g., CVD. The substrate temperature for the deposition of the PSG film 20 is set at, e.g., 600° C.

Then, the surface of the PSG film 20 is polished by, e.g., CMP until the film thickness of the PSG film 20 becomes, e.g., 200 nm to thereby flatten the surface of the PSG film 20.

Next, an SiC film 22 of, e.g., a 50 nm-thickness is formed on the PSG film 20 by, e.g., CVD (see FIG. 5B). The SiC film 22 functions as a passivation film.

Thus, an inter-layer insulation film 24 is formed of the silicon nitride film 18, the PSG film 20 and the SiC film 22 laid the latter on the former.

Next, a contact hole 26 is formed in the SiC film 22, the PSG film 20 and the silicon nitride film 18 down to the silicon substrate 10 by photolithography and dry etching.

Then, a Ti (titanium) film of, e.g., a 15 nm-thickness, a TiN (titanium nitride) film of, e.g., a 15 nm-thickness and a W (tungsten) film of, e.g., a 300 nm-thickness are formed sequentially on the entire surface by, e.g., CVD.

Next, the W film, the TiN film and the Ti film are polished by, e.g., CMP until the surface of the inter-layer insulation film 24 is exposed to thereby remove the W film, the TiN film and the Ti film on the inter-layer insulation film 24. Thus, a contact plug 28 of the Ti film, the TiN film and the W film is formed, buried in the contact hole 26 (see FIG. 5C).

Then, an SiOC film 30 of, e.g., a 150 nm-thickness is formed by, e.g., plasma CVD on the SiC film 22 of the inter-layer insulation film 24 with the contact plug 28 buried in.

Then, a silicon oxide film 32 of, e.g., a 100 nm-thickness is formed on the SiOC film 30 by, e.g., plasma CVD.

Thus, an inter-layer insulation film 34 of the SiOC film 30 and the silicon oxide film 32 laid the latter on the former is formed on the SiC film 22 (see FIG. 5D).

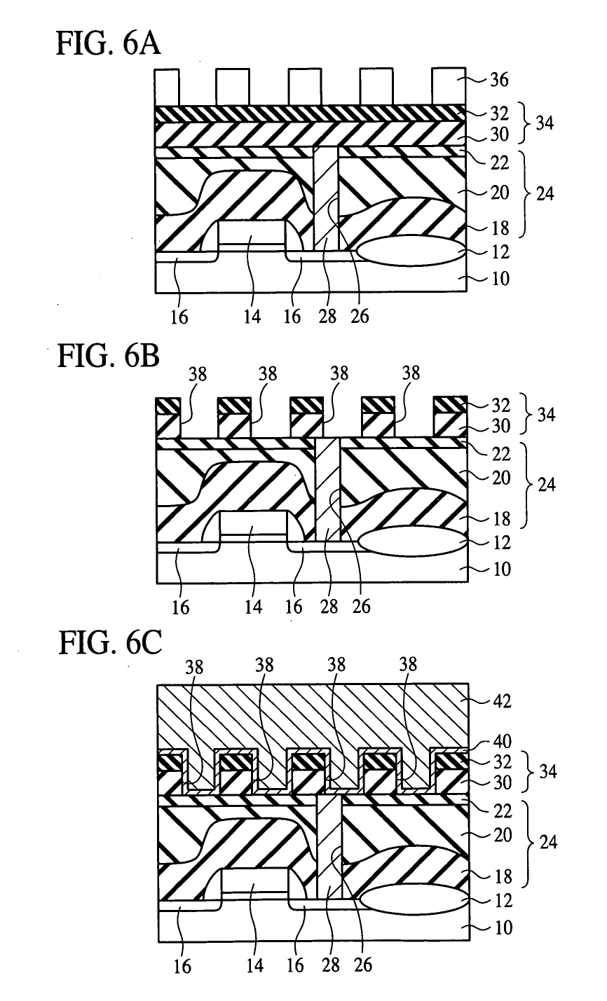

Next, a photoresist film 36 for exposing regions of the inter-layer insulation film 34 for interconnection trenches to be formed in is formed (see FIG. 6A).

Then, with the photoresist film 36 as a mask and the SiC film 22 as a stopper, the silicon oxide film 32 and the SiOC film 30 are sequentially etched. Thus, the interconnection trenches 38 are formed in the silicon oxide film 32 and the SiOC film 30. After the interconnection trenches 38 have been formed, the photoresist film 36 used as the mask is removed (see FIG. 6B).

Next, a barrier metal layer 40 of a TaN (tantalum nitride) film of, e.g., a 30 nm-thickness and a Cu film of, e.g., a 30 nm-thickness are continuously deposited on the entire surface by, e.g., sputtering.

Then, with the Cu film formed on the barrier metal layer 40 as a seed, a Cu film is further deposited by electrolytic plating to form a Cu film 42 of, e.g., a 1 μm-total thickness (see FIG. 6C).

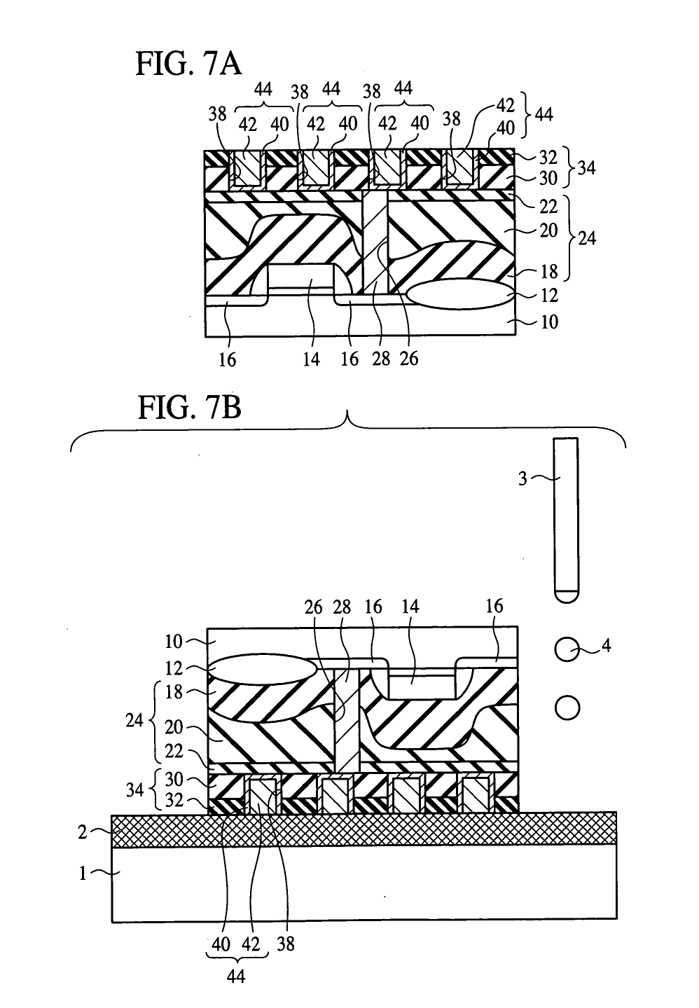

Next, the Cu film 42 and the barrier metal layer 40 are polished by CMP until the silicon oxide film 32 is exposed to remove the Cu film 42 and the barrier metal layer 40 on the silicon oxide film 32. After the Cu film 42 and the barrier metal layer 40 on the silicon oxide film 32 have been removed, prescribed rinsing processing is performed. Thus, an interconnection layer 44 is formed of the barrier metal layer 40 of the TaN film for preventing the diffusion of the Cu and the Cu film 42 forming the major part of the interconnection layer which are buried in the interconnection trench 38 (see FIG. 7A).

After the interconnection layer 44 have been buried by CMP, the polish table 1 is rotated with the surface of the inter-layer insulation film 34 where the surface of the interconnection layer 44 is exposed pressed against the cloth 2 on the polish table 1 of the polish apparatus. Meanwhile the ammonia added hydrogen water 4 is dropped from the nozzle 3 onto the cloth 2 on the polish table 1 (see FIG. 7B). Thus, the cloth-rubbing processing of rubbing the cloth 2 containing the ammonia added hydrogen water is performed on the surface of the interconnection layer 44. The polish apparatus for performing the cloth-rubbing processing is, e.g., a CMP apparatus and the cloth 2 for the ammonia added hydrogen water to be contained is a polish pad for CMP. Specifically, the polish apparatus is, e.g., a CMP apparatus by Applied Materials, Inc. The cloth 2 for the ammonia added hydrogen water to be contained is IC1400, a polish pad by Nitta Haas Incorporated. As the conditions for the cloth-rubbing processing are, for example, the rotation frequency of the polish table 1 is 100 rpm; the pressure for pressing the substrate against the polish table 1 is 0.18 kg/cm²; the ammonia concentration of the ammonia added hydrogen water is 1 ppm; the flow rate of the ammonia added hydrogen water to be fed to the cloth 2 is 150 mL/min; and the processing period of time is 60 seconds.

The cloth-rubbing processing using the ammonia added hydrogen water is thus performed, whereby the surface of the interconnection layer 44 is reduced and is prevented from being oxidized. The surface of the interconnection layer 44 is cleaned. Furthermore, when the semiconductor device is exposed to a high-temperature environment, the migration of the Cu atoms of the interconnection layer 44 is suppressed, and the generation of voids in the interconnection layer 44 can be suppressed. Resultantly, the generation of the conduction defect of the interconnection layer 44 can be suppressed.

After the cloth-rubbing processing using the ammonia added hydrogen water, the nitrogen-two-fluid processing of concurrently spraying the ammonia added hydrogen water and nitrogen gas on the surface of the inter-layer insulation film 34 and the surface of the interconnection layer 44 is performed. As the conditions of the nitrogen-two-fluid processing, for example, the processing period of time is 30 seconds; the ammonia concentration of the ammonia added hydrogen water is 1 ppm; the flow rate of the ammonia added hydrogen water is 150 mL/min; and the flow rate of the nitrogen gas is 50 L/min. It is possible that supersonic vibrations are applied to the ammonia added hydrogen water, and the ammonia added hydrogen water with supersonic vibrations applied, and nitrogen gas are sprayed concurrently on the surface of the inter-layer insulation film 34 and the surface of the interconnection layer 44.

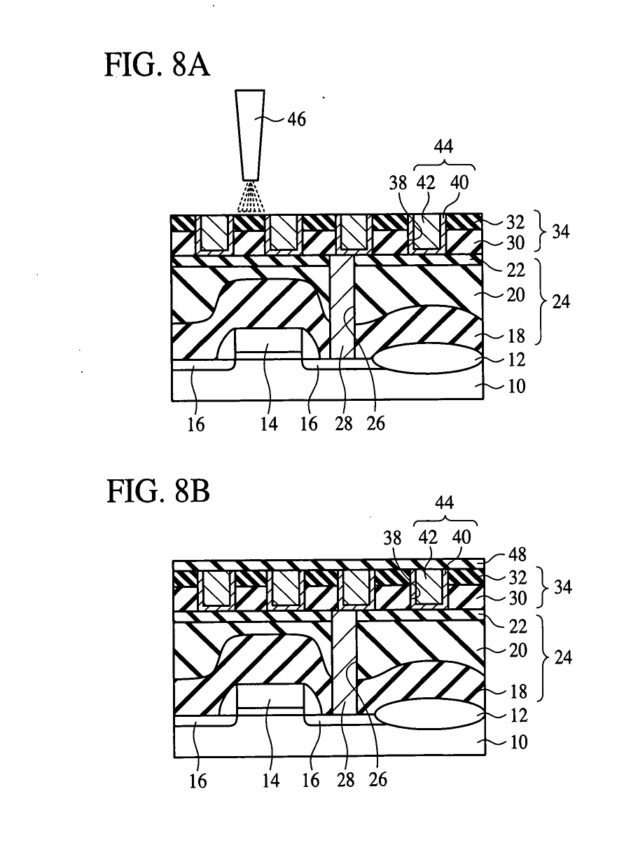

In the nitrogen-two-fluid processing, the ammonia added hydrogen water and nitrogen gas are concurrently sprayed on the surface of the inter-layer insulation film 34 and the surface of the interconnection layer 44 through, e.g., a nozzle 46 of a spray apparatus disposed near the surface of the inter-layer insulation film 34 and the surface of the interconnection layer 44 (see FIG. 8A). At this time, the position of the nozzle 46 is suitably displaced to thereby spray the ammonia added hydrogen water and nitrogen gas at the respective positions. Otherwise, the ammonia added hydrogen water and nitrogen gas are sprayed while the nozzle 46 is being suitably displaced. Thus, the ammonia added hydrogen water and nitrogen are sprayed homogeneously to the entire surface of the interconnection layer 44 buried in the interconnection trench 38.

The nitrogen-two-fluid processing is thus performed, whereby the oxidation of the surface of the interconnection layer 44 is prevented. The surface of the interconnection layer 44 is also cleaned. Furthermore, when the semiconductor device is exposed to a high-temperature environment, the migration of the Cu atoms of the interconnection layer 44 is suppressed, and the generation of the voids in the interconnection layer 44 can be suppressed. Resultantly, the generation of the conduction defect of the interconnection layer 44 can be suppressed.

After the nitrogen-two-fluid processing, hydrogen plasmas are applied to the surface of the inter-layer insulation film 34 and the surface of the interconnection layer 44. The application of the hydrogen plasmas purifies the surface of the inter-layer insulation film 34 and the surface of the interconnection layer 44, and the diffusion preventing film can be formed on the inter-layer insulation film 34 and the interconnection layer 44 with high adhesion. Thus, the semiconductor device can have increased reliability.

After the application of hydrogen plasmas, an SiC film 48 of, e.g., a 50 nm-thickness is formed on the interconnection layer 34 and the interconnection layer 44 by, e.g., plasma CVD (FIG. 8B). The SiC film 48 functions as the diffusion preventing film for preventing the diffusion of the Cu as the interconnection layer material.

Next, an SiOC film 54 of, e.g., a 450 nm-thickness is formed on the SiC film 48 by, e.g., plasma CVD.

Then, a silicon oxide film 56 of, e.g., a 100 nm-thickness is formed on the SiOC film 54 by, e.g., plasma CVD.

Next, a silicon nitride film 58 of, e.g., a 50 nm-thickness is formed on the silicon oxide film 56 by, e.g., plasma CVD. The silicon nitride film 58 is to be used as a hard mask for the etching for forming interconnection trenches, etc. as described later.

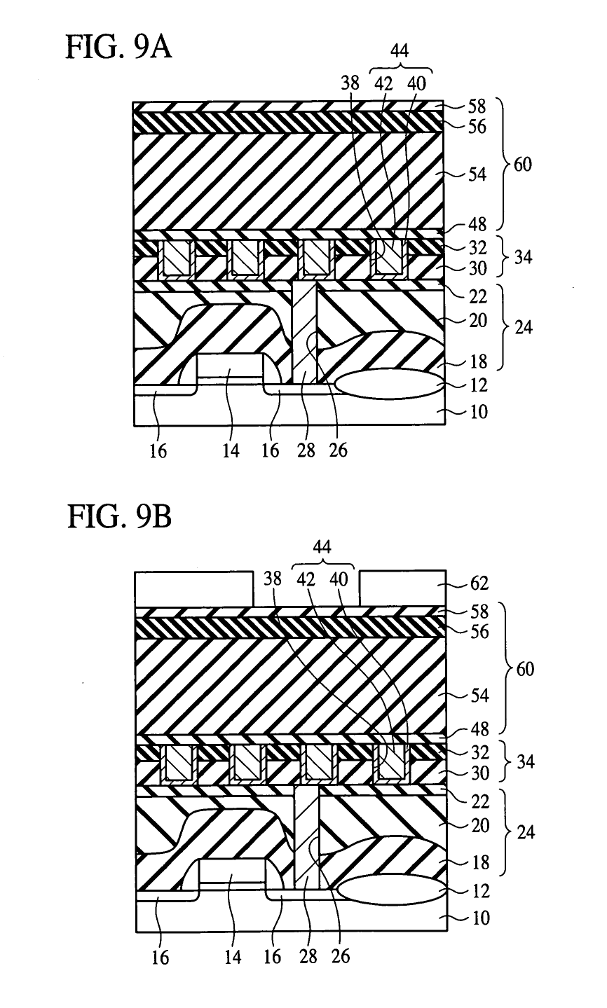

Thus, an inter-layer insulation film 60 of the SiC film 48, the SiOC film 54, the silicon oxide film 56 and the silicon nitride film 58 sequentially laid the latter on the former is formed on the inter-layer insulation film 34 with the interconnection layer 44 buried in the interconnection trench 38 (see FIG. 9A).

Then, a photoresist film 62 for exposing a region for an interconnection layer to be formed in the silicon oxide film 56 and the SiOC film 58 is formed on the silicon nitride film 58 by photolithography (see FIG. 9B).

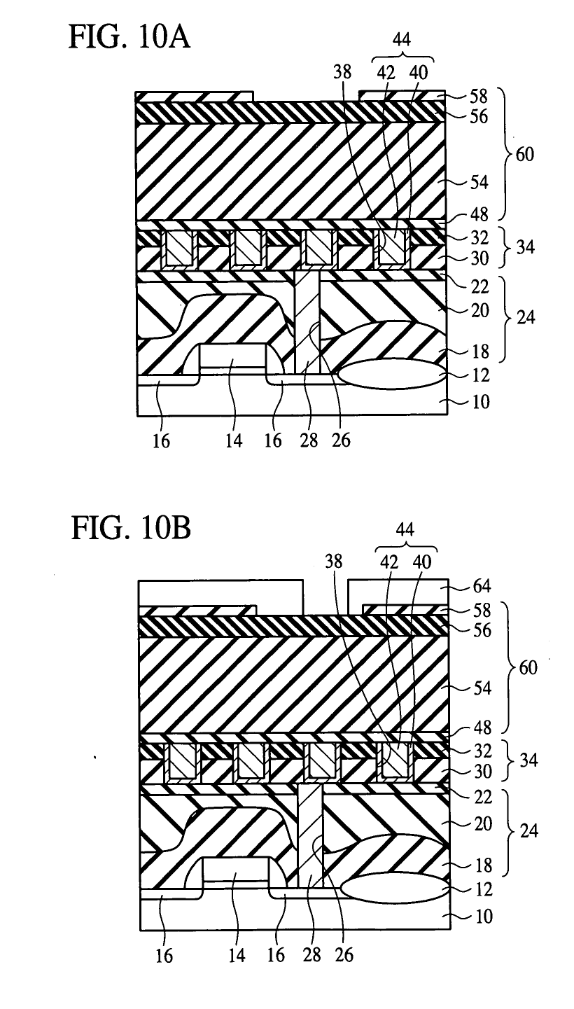

Next, with the photoresist film 62 as a mask, the silicon nitride film 58 is anisotropically etched. After the silicon nitride film 58 has been etched, the photoresist film 62 used as the mask is removed (see FIG. 10A).

Next, a photoresist film 64 for exposing a region for a via hole to be formed in is formed by photolithography on the silicon nitride film 58 and the silicon oxide film 56 exposed by etching the silicon nitride film 58 (see FIG. 10B).

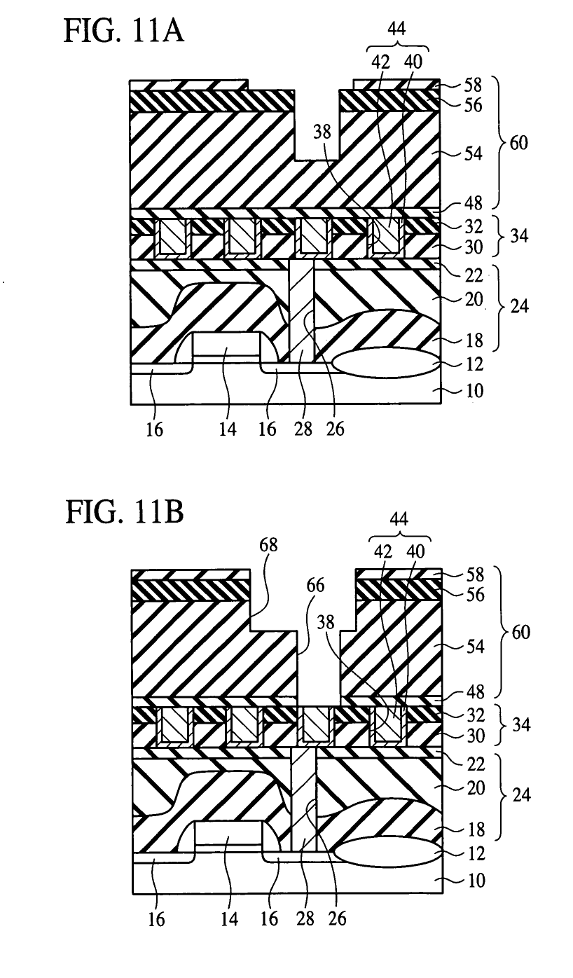

Then, with the photoresist film 64 as a mask, the silicon oxide film 56 and the SiOC film 54 are etched. In this etching, the etching period of time is adjusted so that the etching stops near the center of the SiOC film 54. After the etching has been finished, the photoresist film 64 used as the mask is removed (see FIG. 11A).

Then, with the silicon nitride film 58 as a hard mask, the silicon oxide film 56, the SiOC film 54 and the SiC film 48 are etched. Thus, a via hole 66 for burying a via part of the interconnection layer is formed in the SiOC film 54 and the SiC film 48, and an interconnection trench 68 for burying the interconnection layer is formed in the silicon oxide film 56 and the SiOC film 54 in the region containing the via hole 66 (see FIG. 11B).

Next, a barrier metal layer 70 of TaN film of, e.g., a 30 nm-thickness and a Cu film of, e.g., a 30 nm-thickness are continuously deposited on the entire surface by, e.g., sputtering.

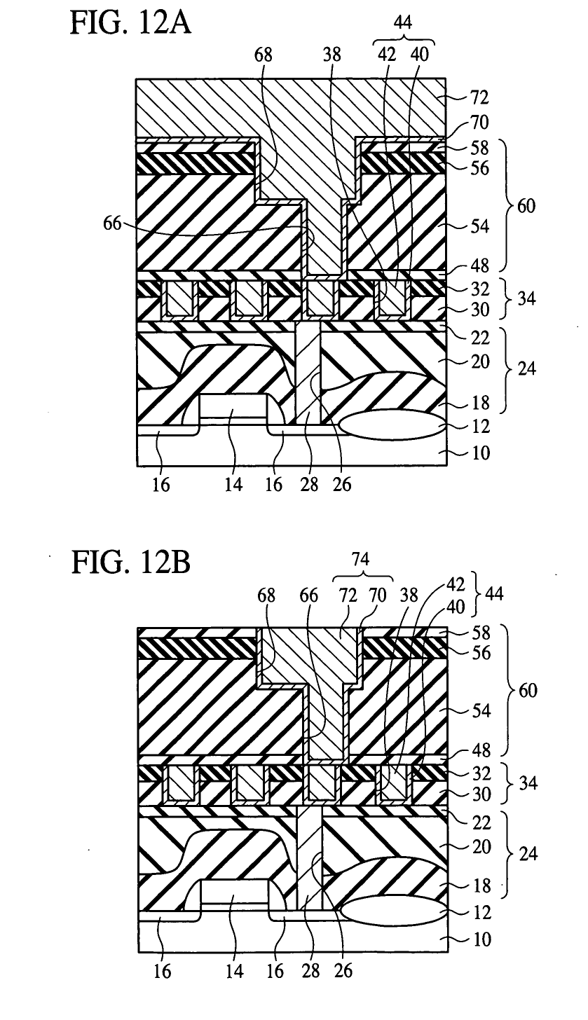

Then, with the Cu film formed on the barrier metal layer 70 as a seed, a Cu film is further deposited by electrolytic plating to form a Cu film 72 of, e.g., a 1 μm-total thickness (see FIG. 12A).

Next, the Cu film 72 and the barrier metal layer 70 of the TaN film are polished by CMP until the silicon nitride film 58 is exposed to remove the Cu film 72 and the barrier metal layer 70 on the silicon nitride film 58. After the Cu film 72 and the barrier metal layer 70 on the silicon nitride film 58 have been removed, prescribed rinsing processing is performed. Thus, an interconnection layer 74 is formed of the barrier metal layer 70 of the TaN film for preventing the diffusion of the Cu and the Cu film 72 forming the major part of the interconnection layer, buried in the via hole 66 and the interconnection trench 68 (see FIG. 12B). The interconnection layer 74 is electrically connected to the interconnection layer 44 via the via part buried in the via hole 66.

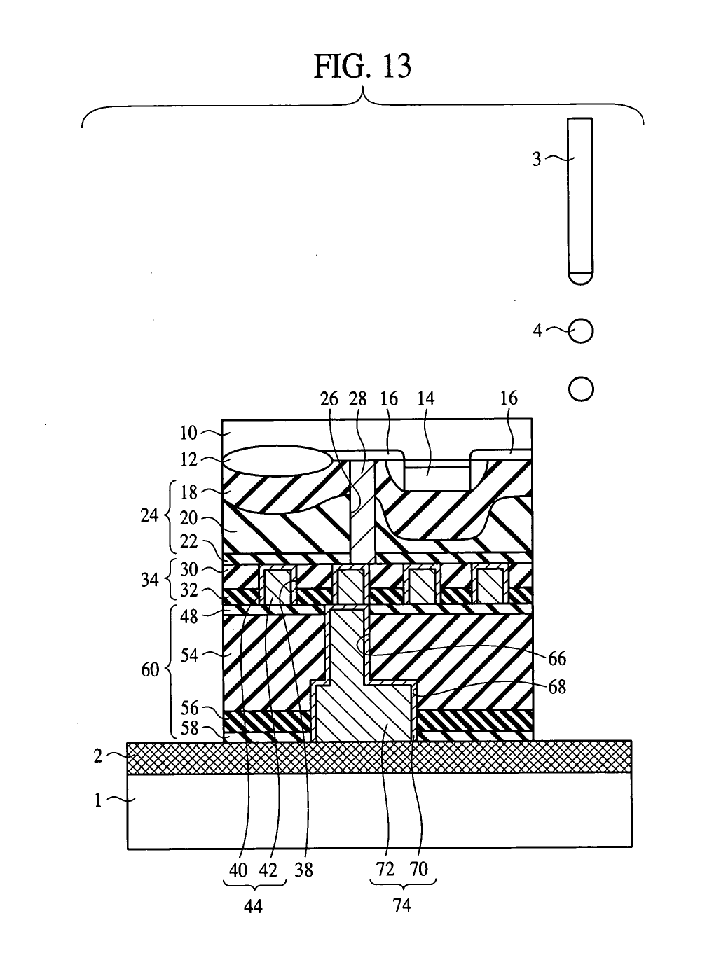

After the interconnection layer 74 has been buried by CMP, in the same way as in forming the interconnection layer 44, the cloth-rubbing processing of rubbing the cloth 2 containing the ammonia added hydrogen water is performed on the surface of the interconnection layer 74 (see FIG. 13). The cloth-rubbing processing using the ammonia added hydrogen water reduces also the surface of the interconnection layer 74 and prevents the oxidation of the surface of the interconnection layer 74. The surface of the interconnection layer 74 is also cleaned. Furthermore, when the semiconductor device is exposed to a high-temperature environment, the migration of the Cu atoms of the interconnection layer 74 can be suppressed, and the generation of voids in the interconnection layer 74 can be suppressed. Resultantly, the generation of the conduction defect of the interconnection layer 74 can be suppressed.

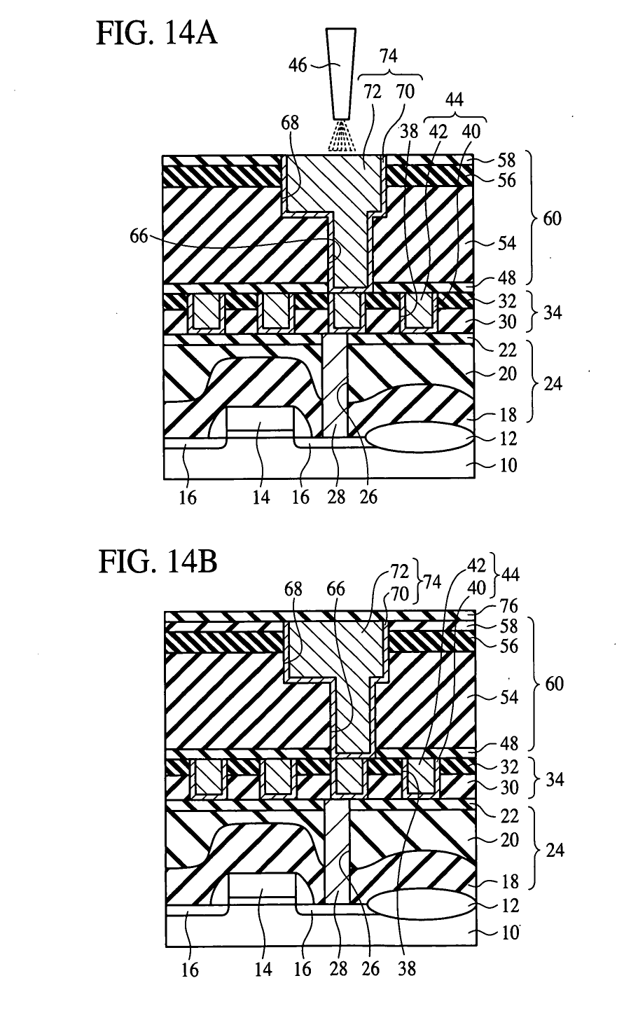

After the cloth-rubbing processing using the ammonia added hydrogen water, in the same way as in forming the interconnection layer 44, the nitrogen-two-fluid processing of concurrently spraying the ammonia added hydrogen water and nitrogen gas is performed on the surface of the inter-layer insulation film 60 and the surface of the interconnection layer 74 (see FIG. 14A). The nitrogen-two-fluid processing reduces also the surface of the interconnection layer 74 and prevents the oxidation of the surface of the interconnection layer 74. The surface of the interconnection layer 74 is also cleaned. Furthermore, when the semiconductor device is exposed to a high-temperature environment, the migration of the Cu atoms of the interconnection layer 74 can be suppressed, and the generation of voids in the interconnection layer 74 can be suppressed. Resultantly, the generation of the conduction defect of the interconnection layer 74 can be suppressed.

After the nitrogen-two-fluid processing, in the same way as in forming the interconnection layer 44, hydrogen plasmas are applied to the surface of the inter-layer insulation film 60 and the surface of the interconnection 74. The application of hydrogen plasmas purifies the surface of the inter-layer insulation film 60 and the surface of the interconnection layer 74, and the diffusion preventing film can be formed on the inter-layer insulation film 60 and the interconnection layer 74 with high adhesion. Thus, the semiconductor device can have increased reliability.

After the application of hydrogen plasmas, an SiC film 76 of, e.g., a 50 nm-thickness is formed on the inter-layer insulation film 60 and the interconnection layer 74 by, e.g., plasma CVD (se FIG. 14B). The SiC film 76 functions as the diffusion preventing film for preventing the diffusion of the Cu as the interconnection layer material.

Hereafter, the same steps as shown in FIGS. 9A-9B, 10A-10B, 11A-11B, 12A-12B, 13 and 14A-14B are suitably repeated to form a multilayer interconnection structure of a plurality of interconnection layers on the silicon substrate 10 with the MOS transistor formed on.

As described above, according to the present embodiment, after the TaN film and the Cu film to be the interconnection layer have been buried in the openings, such as the interconnection trench, the via hole, etc. in the inter-layer insulation film and flattened by CMP and before the SiC film functioning as the diffusion preventing film for preventing the diffusion of Cu as the interconnection material is formed, the cloth-rubbing processing of rubbing the cloth containing the ammonia added hydrogen water on the surface of the interconnection layer is performed, whereby the surface of the interconnection layer can be reduced and prevented from being oxidized. The surface of the interconnection layer can be cleaned. Furthermore, the migration of the Cu atoms of the interconnection layer in a high temperature environment can be suppressed, and the generation of voids in the interconnection layer can be suppressed. Accordingly, the method for fabricating a semiconductor device according to the present embodiment can provide semiconductor devices including interconnection layers of good stress-migration resistance and high reliability.

According to the present embodiment, after the cloth-rubbing processing and the nitrogen-two-fluid processing have been sequentially performed, hydrogen plasmas are applied to the surface of the inter-layer insulation film and the surface of the interconnection layer, whereby the surface of the inter-layer insulation film and the surface of the interconnection layer are cleaned, and the SiC film functioning the diffusion preventing film for preventing the diffusion of Cu as the interconnection material can be formed with high adhesion. Thus, the semiconductor device can have increased reliability.

(Evaluation Result)

Then, the evaluation result of the method for fabricating a semiconductor device according to the present embodiment will be explained. Semiconductor devices having the multilayer interconnection structure which have been fabricated by the method for fabricating a semiconductor device according to the present embodiment were subjected to a high temperature shelf test to measure the rate of generating conduction defects.

The high temperature shelf test is made on semiconductor devices including five interconnection layers and an electrode pad of aluminum formed with a silicon oxide film as an inter-layer insulation film fabricated by the method for fabricating a semiconductor device according to the present embodiment. Example 1 on which the high temperature shelf test was made is as follows.

In Example 1, the cloth-rubbing processing of rubbing a cloth containing the ammonia added hydrogen water, and the nitrogen-two-fluid processing of concurrently spraying the ammonia added hydrogen water and nitrogen gas were performed. In the cloth-rubbing processing, the polish apparatus was a CMP apparatus by Applied Materials, Inc.; the cloth to contain the ammonia added hydrogen water is a polish pad, IC1400 by Nitta Haas Incorporated; the rotation frequency of the polish table was 100 rpm; the pressure for pressing the substrate to the polish table was 0.18 kg/cm²; the ammonia concentration of the ammonia added hydrogen water was 1 ppm; the flow rate of the ammonia added hydrogen water to be fed to the cloth was 150 mL/min; the processing period of time was 60 seconds. In the nitrogen-two-fluid processing, the ammonia concentration of the ammonia added hydrogen water was 1 ppm; the flow rate of the ammonia added hydrogen water was 150 mL/min; the flow rate of the nitrogen gas was 50 L/min; and the processing period of time was 30 seconds.

In the high temperature self tests, the temperature at which the semiconductor device stood was 235° C., and the periods of time for the semiconductor device stood were 70 hours, 170 hours, 340 hours and 500 hours. The rate of the generation of conduction defects were measured in each case.

The same high temperature shelf tests were made on the following Controls 1 and 2.

In Control 1, an interconnection layer was buried in an interconnection trench and flattened by CMP, then the nitrogen-two-fluid processing of concurrently blowing the ammonia added hydrogen water and nitrogen gas has been performed without the cloth-rubbing processing, and then a diffusion prevention film was formed. In the nitrogen-two-fluid processing, the ammonia concentration of the ammonia added hydrogen water was 1 ppm; the flow rate of the ammonia added hydrogen water was 150 mL/min; the flow rate of the nitrogen gas was 50 L/min; the processing period of time was 30 seconds; and 1 MHz and 60 W supersonic vibrations were applied to the ammonia added hydrogen water.

In Control 2, an interconnection layer was buried in an interconnection trench and flattened by CMP, and then immediately a diffusion prevention film was formed without the cloth-rubbing processing and the nitrogen-two-fluid processing.

The semiconductor devices according to Controls 1 and 2 were fabricated in the same way as in Example 1 except that the cloth-rubbing processing was not performed and that neither the cloth-rubbing processing and the nitrogen-two-fluid processing was performed.

The results of the high temperature shelf tests on Example 1, Control 1 and Control 2 are as follows.

In Example 1, the generation rates of conduction defects were 0% respectively for the standing periods of time of 70 hours, 170 hours, 340 hours and 500 hours.

In Control 1, the generation rates of conduction defects were 1%, 3%, 7% and 11% respectively for the standing periods of time of 70 hours, 170 hours, 340 hours and 500 hours.

In Control 2, the generation rates of conduction defects were 10%, 32%, 55% and 68% respectively for the standing periods of time of 70 hours, 170 hours, 340 hours and 500 hours.

Based on the result of the high temperature shelf tests described above, it has been confirmed that the method for fabricating a semiconductor device according to the present embodiment can much drastically decrease the generation rate of conduction defects in a high temperature environment in comparison with the conventional methods.

### A Second Embodiment

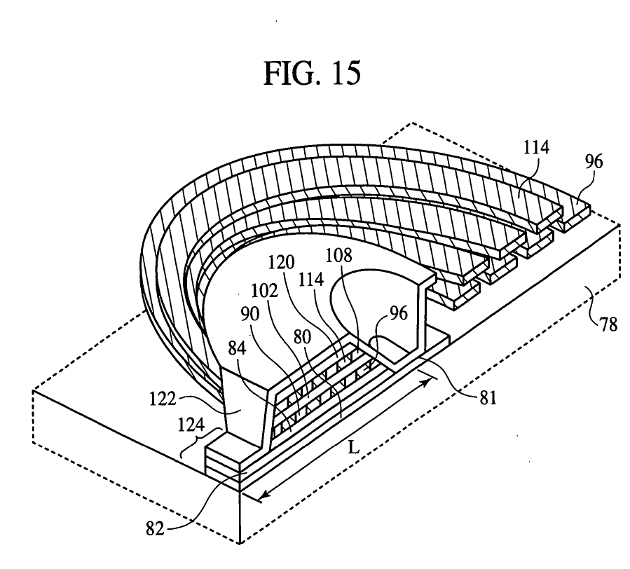

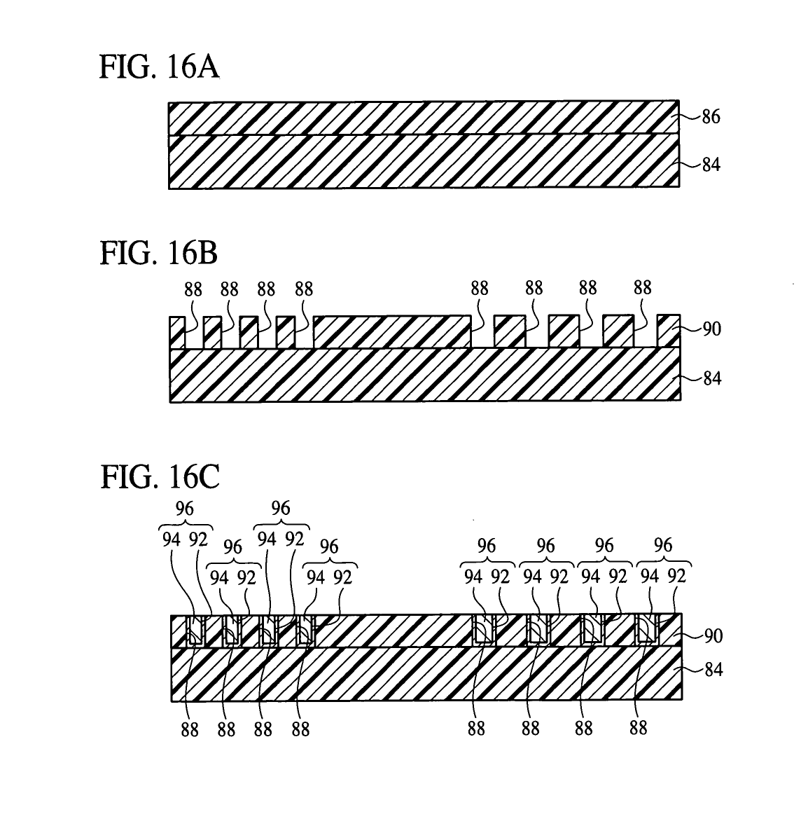

The method for fabricating a magnetic head according to a second embodiment of the present invention will be explained with reference to FIGS. 15, 16A-16C, 17A-17B, 18A-18B, 19A-19B and 20A-20B. FIG. 15 is a perspective of a magnetic head, which illustrates a structure thereof. FIGS. 16A-16C, 17A-17B, 18A-18B, 19A-19B and 20A-20B are sectional views of the magnetic head in the steps of the method for fabricating the same according to the present embodiment, which show the method.

FIG. 15 illustrates the structure of the induction type thin-film magnetic head for hard discs. FIGS. 16A-16C, 17A-17B, 18A-18B, 19A-19B and 20A-20B illustrate the steps forming the first layer and the second layer of the coil of the induction type thin-film magnetic head illustrated in FIG. 15. In FIGS. 16A-16C, 17A-17B, 18A-18B, 19A-19B and 20A-20B, the members except the coil are suitably omitted. In the following description, the reproduction head will be omitted, and only the induction type thin-film magnet head will be explained.

First, as illustrated in FIG. 15, an Al₂O₃ film (not illustrated) is formed on an Al₂O₃—TiC substrate 78 which is to be the base of the slider after a recording element layer (not illustrated) is formed in a prescribed pattern, and then a lower magnetic core layer 80 of a prescribed pattern is formed of NiFe alloy.

Then, a write gap layer 82 of Al₂O₃ is formed on a lower magnetic core layer 80 by sputtering or others. A contact part 81 of the lower magnetic core layer 80, which is to be connected to an upper magnetic core layer 122 in a later step, is exposed.

Then, a resist is applied to the a write gap layer 82, is patterned in a prescribed pattern, and is heated to, e.g., 200° C. and cured to form an inter-layer insulation film 84, of, e.g., a 3.5 μm-thickness. In FIG. 15, the inter-layer insulation films are omitted except between the lower magnetic core layer 80 and the upper magnetic core layer 122.

Then, a resist 86 is applied to the inter-layer insulation film 84 (see FIG. 16A), and an interconnection trench 88 of the first layer, having a plane spiral coil pattern is formed and is heated to, e.g., 200° C. to be cured. Thus, an inter-layer insulation film 90 of, e.g. a 3 μm-thickness having the interconnection trench 88 having the coil pattern of the first layer is formed (see FIG. 16B).

Next, a barrier metal layer 92 of a TaN film of, e.g., a 30 nm-thickness and a Cu film of, e.g., a 30 nm-thickness are continuously deposited on the entire surface by, e.g., sputtering.

Next, with the Cu film formed on the barrier metal layer 92 as a seed, a Cu film is further deposited by electrolytic plating to form a Cu film 94 of, e.g., a 3 μm-total thickness.

Then, the Cu film 94 and the barrier metal layer 92 are polished by CMP until the inter-layer insulation film 90 is exposed to remove the Cu film 94 and the barrier metal layer 92 on the inter-layer insulation film 90. After the Cu film 94 and the barrier metal layer 92 on the inter-layer insulation film 90 have been removed, prescribed rinsing processing is performed. Thus, an interconnection layer 96 is formed of the barrier metal layer 92 of the TaN film for preventing the diffusion of the Cu and the Cu film 94 forming the major part of the interconnection layer, buried in the interconnection trench 88 (see FIG. 16C). The interconnection layer 96 forms the plane spiral coil of the first layer.

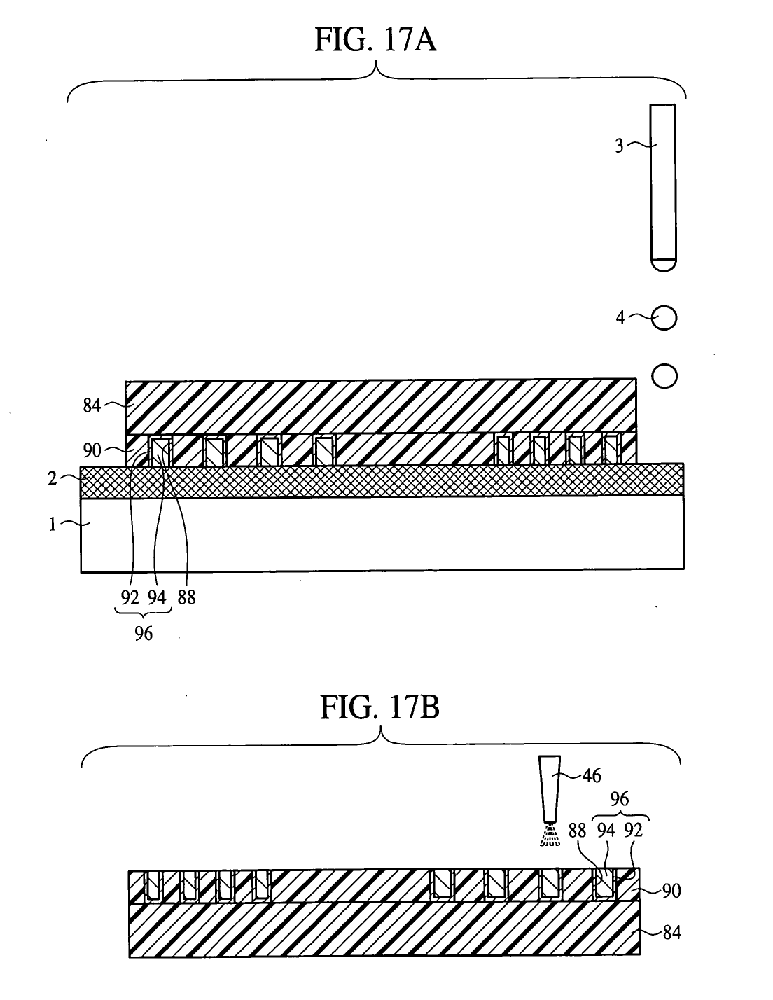

After the interconnection layer 96 have been buried by CMP, the polish table 1 is rotated with the surface of the inter-layer insulation film 90 where the surface of the interconnection layer 96 is exposed pressed against the cloth 2 on the polish table 1 of the polish apparatus. Meanwhile the ammonia added hydrogen water 4 is dropped from the nozzle 3 onto the cloth 2 on the polish table 1 (see FIG. 17A). Thus, the cloth-rubbing processing of rubbing the cloth 2 containing the ammonia added hydrogen water is performed on the surface of the interconnection layer 96. The polish apparatus for performing the cloth-rubbing processing is, e.g., a CMP apparatus and the cloth 2 for the ammonia added hydrogen water to be contained is a polish pad for CMP. Specifically, the polish apparatus is, e.g., a CMP apparatus by Applied Materials, Inc. The cloth 2 for the ammonia added hydrogen water to be contained is IC1400, a polish pad by Nitta Haas Incorporated. As the conditions for the cloth-rubbing processing are, for example, the rotation frequency of the polish table 1 is 70 rpm; the pressure for pressing the substrate against the polish table 1 is 0.18 kg/cm²; the ammonia concentration of the ammonia added hydrogen water is 1 ppm; the flow rate of the ammonia added hydrogen water to be fed to the cloth 2 is 200 mL/min; and the processing period of time is 60 seconds.

The cloth-rubbing processing using the ammonia added hydrogen water is thus performed, whereby the surface of the interconnection layer 96 is reduced and is prevented from being oxidized. The surface of the interconnection layer 96 is cleaned. Furthermore, when the magnetic head is exposed to a high-temperature environment, the migration of the Cu atoms of the interconnection layer 96 is suppressed, and the generation of voids in the interconnection layer 96 can be suppressed. Resultantly, the generation of the conduction defect of the interconnection layer 96 can be suppressed.

After the cloth-rubbing processing using the ammonia added hydrogen water has been performed, the nitrogen-two-fluid processing of concurrently spraying the ammonia added hydrogen water prepared by solving ammonia and hydrogen in pure water, and nitrogen gas is performed on the surface of the inter-layer insulation film 90 and the surface of the interconnection layer 96 (see FIG. 17B). As the conditions for the nitrogen-two-fluid processing, for example, the processing period of time is 30 seconds; the ammonia concentration of the ammonia in the ammonia added hydrogen water is 1 ppm; the flow rate of the ammonia added hydrogen water is 150 mL/min; and the flow rate of the nitrogen gas is 50 L/min. It is possible that supersonic vibrations are in advance applied to the ammonia added hydrogen water, and the ammonia added hydrogen water with supersonic vibrations applied to and nitrogen gas may be concurrently sprayed on the surface of the inter-layer insulation film 90 and the surface of the interconnection layer 96.

The nitrogen-two-fluid processing is thus performed, whereby the oxidation of the surface of the interconnection layer 96 is prevented. The surface of the interconnection layer 96 is also cleaned. Furthermore, when the magnetic head is exposed to a high-temperature environment, the migration of the Cu atoms of the interconnection layer 96 is suppressed, and the generation of the voids in the interconnection layer 96 can be suppressed. Resultantly, the generation of the conduction defect of the interconnection layer 96 can be suppressed.

After the nitrogen-two-fluid processing, hydrogen plasmas are applied to the surface of the inter-layer insulation film 90 and the surface of the interconnection layer 96. The application of the hydrogen plasmas purifies the surface of the inter-layer insulation film 90 and the surface of the interconnection layer 96, and the diffusion preventing film can be formed on the inter-layer insulation film 90 and the interconnection layer 96 with high adhesion. Thus, the magnetic head can have increased reliability.

After the application of the hydrogen plasma, an SiC film 98 of, e.g., a 50 nm-thickness is formed on the inter-layer insulation film 90 and the interconnection layer 96 by, e.g., plasma CVD. The SiC film 98 functions as the diffusion preventing film for preventing the diffusion of Cu as the interconnection layer material.

Then, a resist is applied to the SiC film 98 and patterned in a prescribed pattern and is heated to, e.g., 200° C. and cured to form an insulation film 100 of, e.g., 3.5 μm-thickness.

Thus, an inter-layer insulation film 102 of the SiC film 98 and the insulation film 100 sequentially laid the latter on the former is formed.

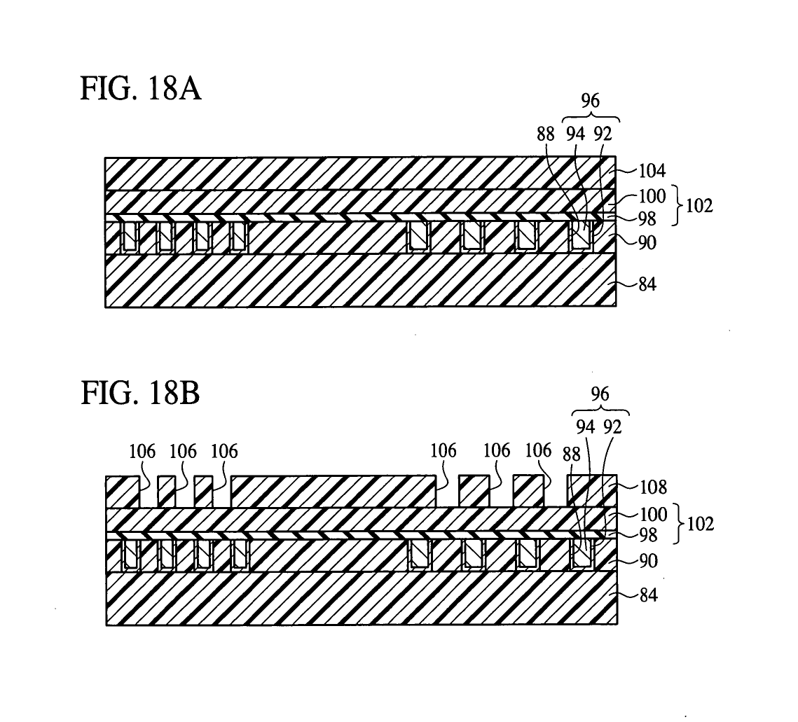

Next, a resist 104 is applied to the inter-layer insulation film 102 (see FIG. 18A), and interconnection trench 106 of the second layer, having a plane spiral coil pattern is formed and is heated to, e.g., 200° C. to be cured. Thus, an inter-layer insulation film 108 of, e.g., a 3 μm-thickness, having the interconnection trench 106 having the coil pattern of the second layer is formed (see FIG. 18B).

Next, a barrier metal layer 110 of TaN film of, e.g., a 30 nm-thickness and a Cu film of, e.g., a 30 nm-thickness are continuously deposited on the entire surface by, e.g., sputtering.

Next, with the Cu film formed on the barrier metal layer 110 as a seed, a Cu film is further deposited by electrolytic plating to form a Cu film 112 of, e.g., a 3 μm-total thickness.

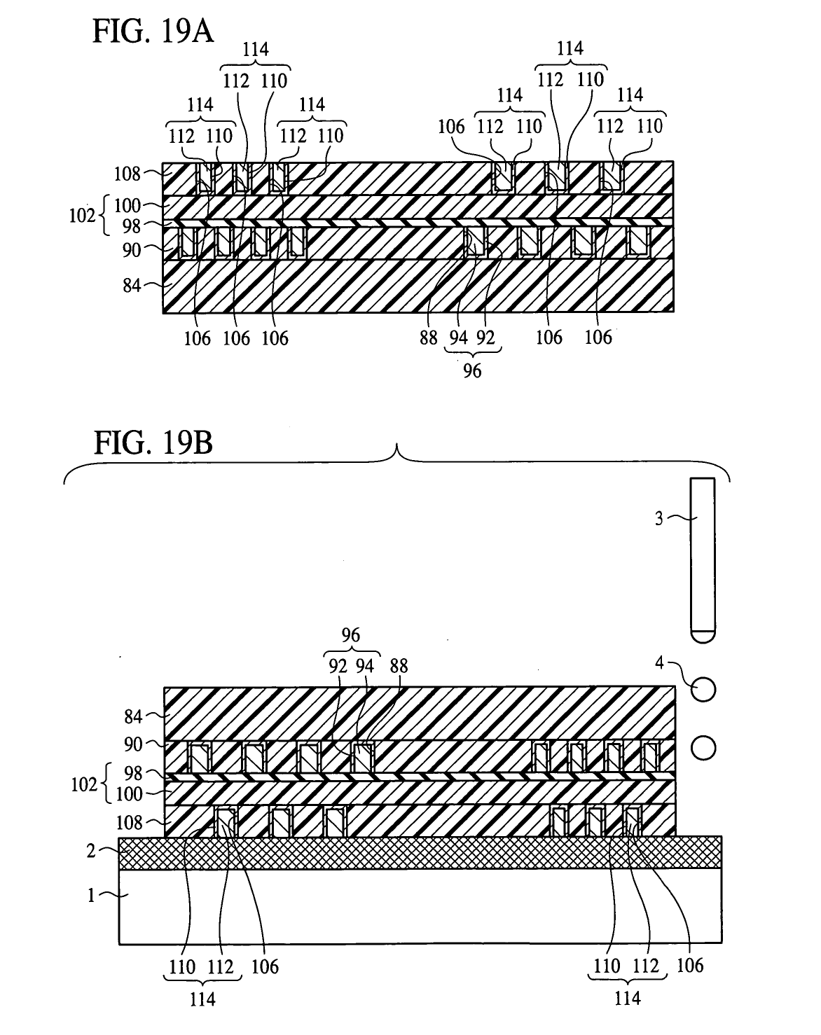

Then, the Cu film 112 and the barrier metal layer 110 are polished by CMP until the inter-layer insulation film 108 is exposed to remove the Cu film 112 and the barrier metal layer 110 on the inter-layer insulation film 108. The Cu film 112 and the barrier metal layer 110 on the inter-layer insulation film 108 have been removed, prescribed rinsing processing is performed. Thus, an interconnection layer 114 is formed of the barrier metal layer 110 of the TaN film for preventing the diffusion of the Cu and the Cu film 112 forming the major part of the interconnection layer, buried in the interconnection trench 106 (see FIG. 19A). The interconnection layer 114 forms the plane spiral coil of the second layer.

After the interconnection layer 114 has been buried by CMP, in the same way as in forming the interconnection layer 96, the cloth-rubbing processing of rubbing the cloth 2 containing the ammonia added hydrogen water is performed on the surface of the interconnection layer 114 (see FIG. 19B). The cloth-rubbing processing using the ammonia added hydrogen water reduces also the surface of the interconnection layer 114 and prevents the oxidation of the surface of the interconnection layer 114. The surface of the interconnection layer 114 is also cleaned. Furthermore, when the magnetic head is exposed to a high-temperature environment, the migration of the Cu atoms of the interconnection layer 114 can be suppressed, and the generation of voids in the interconnection layer 114 can be suppressed. Resultantly, the generation of the conduction defect of the interconnection layer 114 can be suppressed.

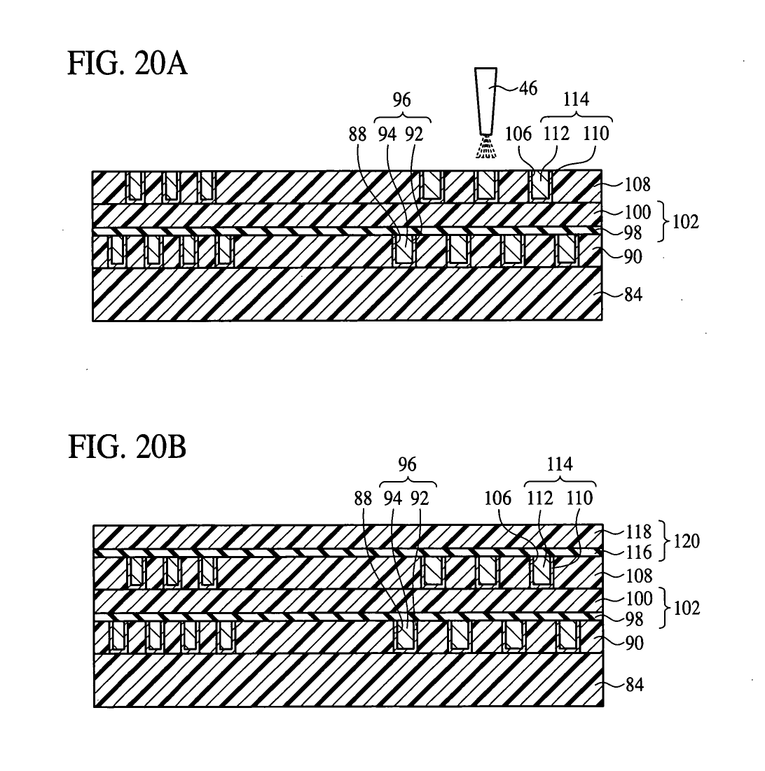

After the cloth-rubbing processing using the ammonia added hydrogen water, in the same way as in forming the interconnection layer 96, the nitrogen-two-fluid processing of concurrently spraying the ammonia added hydrogen water and nitrogen gas is performed on the surface of the inter-layer insulation film 108 and the surface of the interconnection layer 114 (see FIG. 20A). The nitrogen-two-fluid processing reduces also the surface of the interconnection layer 114 and prevents the oxidation of the surface of the interconnection layer 114. The surface of the interconnection layer 114 is also cleaned. Furthermore, when the magnetic head is exposed to a high-temperature environment, the migration of the Cu atoms of the interconnection layer 114 can be suppressed, and the generation of voids in the interconnection layer 114 can be suppressed. Resultantly, the generation of the conduction defect of the interconnection layer 114 can be suppressed.

After the nitrogen-two-fluid processing, in the same way as in forming the interconnection layer 96, hydrogen plasmas are applied to the surface of the inter-layer insulation film 108 and the surface of the interconnection layer 114. The application of hydrogen plasmas purifies the surface of the inter-layer insulation film 108 and the surface of the interconnection layer 114, and the diffusion preventing film can be formed on the inter-layer insulation film 108 and the interconnection layer 114 with high adhesion. Thus, the magnetic head can have increased reliability.

After the application of the hydrogen plasma, an SiC film 116 of, e.g., a 50 nm-thickness is formed on the inter-layer insulation film 108 and the interconnection layer 114 by, e.g., plasma CVD. The SiC film 116 functions as the diffusion preventing film for preventing the diffusion of the Cu as the interconnection layer material.

Then, a resist is applied to the SiC film 116 and patterned in a prescribed pattern and is heated to, e.g., 200° C. and cured to form an insulation film 118 of, e.g., a 3.5 μm-thickness.

Thus, an inter-layer insulation film 120 of the SiC film 116 and the insulation film 118 sequentially laid the latter on the former is formed (see FIG. 20B).

Next, a NiFe plating seed layer (not illustrated) is formed by sputtering, and with a photoresist mask (not illustrated) as a plating frame, a NiFe is selectively electrolytically plated to form the upper magnetic core layer 122 illustrated in FIG. 15. Then, the photoresist mask is removed, and then the exposed NiFe plating seed layer is removed by ion milling.

Then, an Al₂O₃ film as a protection film (not illustrated) is formed on the entire surface, the Al₂O₃—TiC substrate 78 is cut, and then slider machining by grinding, polish, etc. is made for adjusting the length of the magnetic core forward end 124, i.e., the gap depth. Thus, the magnetic head illustrated in FIG. 15 is completed. In FIG. 15, the core length is indicated by L.

As described above, according to the present embodiment, after the TaN film and the Cu film to be the interconnection layer have been buried in the interconnection trench in the inter-layer insulation film and flattened by CMP and before the SiC film functioning as the diffusion preventing film for preventing the diffusion of Cu as the interconnection material is formed, the cloth-rubbing processing of rubbing the cloth containing the ammonia added hydrogen water on the surface of the interconnection layer is performed, whereby the surface of the interconnection layer can be reduced and prevented from being oxidized. The surface of the interconnection layer can be cleaned. Furthermore, the migration of the Cu atoms of the interconnection layer in a high temperature environment can be suppressed, and the generation of voids in the interconnection layer can be suppressed. Accordingly, the method for fabricating a magnetic head according to the present embodiment can provide magnetic heads including interconnection layers of good stress-migration resistance and high reliability.

According to the present embodiment, after the cloth-rubbing processing and the nitrogen-two-fluid processing have been sequentially performed, hydrogen plasmas are applied to the surface of the inter-layer insulation film and the surface of the interconnection layer, whereby the surface of the inter-layer insulation film and the surface of the interconnection layer are cleaned, and the SiC film functioning the diffusion preventing film for preventing the diffusion of Cu as the interconnection material can be formed with high adhesion. Thus, the magnetic head can have increased reliability.

(Evaluation Result)

Next, the evaluation result of the method for fabricating a magnetic head according to the present embodiment will be explained. Magnetic heads having the multilayer interconnection structure which have been fabricated by the method for fabricating a magnetic head according to the present embodiment were subjected to a high temperature shelf test to measure the rate of generating conduction defects.

Examples 2 and 3 on which the high temperature shelf tests were made are as follows.

In Example 2, the cloth-rubbing processing of rubbing a cloth containing the ammonia added hydrogen water, and the nitrogen-two-fluid processing of concurrently spraying the ammonia added hydrogen water and nitrogen gas were performed. In the cloth-rubbing processing, the polish apparatus was a CMP apparatus by Applied Materials, Inc.; the cloth to contain the ammonia added hydrogen water is a polish pad, IC1400 by Nitta Haas Incorporated; the rotation frequency of the polish table was 70 rpm; the pressure for pressing the substrate to the polish table was 0.18 kg/cm²; the ammonia concentration of the ammonia added hydrogen water was 1 ppm; the flow rate of the ammonia added hydrogen water to be fed to the cloth was 200 mL/min; the processing period of time was 60 seconds. In the nitrogen-two-fluid processing, the ammonia concentration of the ammonia added hydrogen water was 1 ppm; the flow rate of the ammonia added hydrogen water was 150 mL/min; the flow rate of the nitrogen gas was 50 L/min; and the processing period of time was 30 seconds.

In Example 3, a silicon oxide film was formed by PECVD using TEOS (tetraethoxysilane) in place of the insulation films 84, 90, 100, 108 of resist in Example 2. The cloth-rubbing processing and the nitrogen-two-fluid processing were performed in the same way as in Example 2.

The same high temperature shelf tests were made on the following Controls 3 and 4.

In Control 3, the magnetic head was fabricated in the same way as in Example 2 except that the cloth-rubbing processing and the nitrogen-two-fluid processing were not performed.

In Control 4, the magnetic head was fabricated in the same way as in Example 3 except that the cloth-rubbing processing and the nitrogen-two-fluid processing were not performed.

In the high temperature self tests, the temperature at which the magnetic head stood was set at 140° C. respectively in Example 2 and Control 3, 240° C. respectively in Example 3 and Control 4. The periods of time for the magnetic head stood were 70 hours, 170 hours, 340 hours and 500 hours. The rate of the generation of conduction defects were measured in each case.

The results of the high temperature shelf tests on Example 2, Example 3, Control 3 and Control 4 are as follows.

In Example 2, the generation rates of conduction defects were 0%, 0%, 3% and 5% respectively for the standing periods of time of 70 hours, 170 hours, 340 hours and 500 hours.

In Example 3, the generation rates of conduction defects were 0% respectively for the standing periods of time of 70 hours, 170 hours, 340 hours and 500 hours.

In Control 3, the generation rates of conduction defects were 19%, 31%, 54% and 86% respectively for the standing periods of time of 70 hours, 170 hours, 340 hours and 500 hours.

In Control 4, the generation rates of conduction defects were 10%, 28%, 53% and 71% respectively for the standing periods of time of 70 hours, 170 hours, 340 hours and 500 hours.

Based on the result of the high temperature shelf tests described above, it has been confirmed that the method for fabricating a magnetic head according to the present embodiment can much drastically decrease the generation rate of conduction defects in a high temperature environment in comparison with the conventional methods. In comparison of the result of Example 2 with the result of Example 3, it is found that as the insulation film forming the inter-layer insulation film, the use of a silicon oxide film more decreases the generation ratio of the conduction defect than the use of a resist film.

### Modified Embodiments

The present invention is not limited to the above-described embodiments and can cover other various modifications.

For example, in the above-described embodiments, the cloth-rubbing processing is performed in combination with the nitrogen-two-fluid processing. The cloth-rubbing processing may not be performed in combination with the nitrogen-two-fluid processing but may be performed singly. That is, it is possible that the cloth-rubbing processing is performed singly after an interconnection layer has been formed, and without the nitrogen-two-fluid processing, the diffusion prevention film is formed on an inter-layer insulation film with the interconnection layer buried in.

In the above-described embodiments, after the cloth-rubbing processing, the nitrogen-two-fluid processing is performed. However, the nitrogen-two-fluid processing may be performed before the cloth-rubbing processing.

In the above-described embodiments, in the nitrogen-two-fluid processing, the water to be sprayed concurrently with nitrogen gas is the ammonia added hydrogen water. However, the water to be sprayed concurrently with nitrogen gas in the nitrogen-two-fluid processing can be suitably pure water, carbonated water with carbonic acid dissolved in pure water, hydrogen water with hydrogen solved in pure water, ammonia added hydrogen water or others.

In the above-described embodiments, in the cloth-rubbing processing, the cloth containing the ammonia added hydrogen water is caused to rub against the surface of an interconnection layer. However, the cloth containing hydrogen water without ammonia solved may be caused to rub against the surface of an interconnection layer.

In the above-described embodiments, SiOC film, silicon oxide film, resist film, etc. are used for the inter-layer insulation films. However, the inter-layer insulation films are not essentially formed of them and can be formed of various insulation films. As the inter-layer insulation films, a wide variety of insulation films of inorganic insulation materials containing Si (silicon) and O (oxygen) and organic insulation materials such as hydrocarbon containing C (carbon) and H (hydrogen), etc. can be used.

In the above-described embodiments, SiC film is formed as the diffusion preventing films for preventing the diffusion of Cu as the interconnection material. However, the films formed as the diffusion preventing films for Cu are not limited to SiC film. As the diffusion preventing films for Cu, in place of SiC film, silicon nitride film, polyimide film, zirconium nitride film, etc. may be formed.

In the first embodiment described above, in forming the interconnection layer 74, the TaN film 70 and the Cu film 72 are simultaneously buried in the via hole 66 and the interconnection trench 68 by dual damascene process. However, the via hole and the interconnection trench are formed independently of each other, and a TaN film and a Cu film may be buried by the single damascene process.

In the above-described embodiments, the semiconductor device and the magnetic head are fabricated. However, the present invention is applicable widely to methods for fabricating interconnection structures including interconnection layers formed of Cu as the main material.

What is claimed is:

1. A method for fabricating a semiconductor device comprising the steps of:
forming an opening in an insulation film;
forming an interconnection layer of Cu as a main material in the opening; and
performing cloth-rubbing processing of rubbing a cloth containing pure water with ammonia and hydrogen solved in on a surface of the interconnection layer buried in the opening.

2. A method for fabricating a semiconductor device according to claim 1, further comprising, after the step of performing cloth-rubbing processing, the step of forming a diffusion preventing film for preventing the diffusion of Cu on the insulation film and the interconnection layer.

3. A method for fabricating a semiconductor device according to claim 2, wherein
the diffusion preventing film is an SiC film or a silicon nitride film.

4. A method for fabricating a semiconductor device according to claim 1, further comprising, after the step of forming the interconnection layer and before the step of performing cloth-rubbing processing or after the step of performing cloth-rubbing processing, the step of
performing nitrogen-two-fluid processing of concurrently spraying water and nitrogen gas on the surface of the interconnection layer buried in the opening.

5. A method for fabricating a semiconductor device according to claim 4, wherein
the water to be sprayed concurrently with the nitrogen gas in the step of performing nitrogen-two-fluid processing is pure water with ammonia and hydrogen solved in.

6. A method for fabricating a semiconductor device according to claim 1, further comprising, after the step of performing cloth-rubbing processing, the step of
applying hydrogen plasmas to a surface of the insulation film and the surface of the interconnection layer.

7. A method for fabricating a semiconductor device according to claim 1, wherein
in the step of forming the interconnection layer, the interconnection layer is formed of a conduction film by forming the conduction film on the insulation film with the opening formed in, polishing the conduction film to expose the insulation film and bury the conduction film in the opening.

8. A method for fabricating a semiconductor device according to claim 7, wherein
in the step of forming the opening, the opening containing a via hole and an interconnection trench formed in a region containing the via hole is formed.

9. A method for fabricating a magnetic head comprising the steps of:
forming an opening of a pattern of a coil in an insulation film;
forming an interconnection layer formed of Cu as a main material and forming a coil in the opening; and
performing cloth-rubbing processing of rubbing a cloth containing pure water with ammonia and hydrogen solved in on a surface of the interconnection layer buried in the opening.

10. A method for fabricating a magnetic head according to claim 9, further comprising, after the step of performing cloth-rubbing processing, the step of
forming a diffusion preventing film for preventing the diffusion of Cu on the insulation film and the interconnection layer.

11. A method for fabricating a magnetic head according to claim 10, wherein
the diffusion prevention film is an SiC film or a silicon nitride film.

12. A method for fabricating a magnetic head according to claim 9, further comprising, after the step of forming the interconnection layer and before the step of performing cloth-rubbing processing or after the step of performing cloth-rubbing processing, the step of
performing nitrogen-two-fluid processing of concurrently spraying water and nitrogen gas on the surface of the interconnection layer buried in the opening.

13. A method for fabricating a magnetic head according to claim 12, wherein
the water to be sprayed concurrently with the nitrogen gas in the step of performing nitrogen-two-fluid processing is pure water with ammonia and hydrogen solved in.

14. A method for fabricating a magnetic head according to claim 9, further comprising, after the step of performing cloth-rubbing processing, the step of
applying hydrogen plasmas to a surface of the insulation film and the surface of the interconnection layer.

15. A method for fabricating a magnetic head according to claim 9, wherein
in the step of forming the interconnection layer, the interconnection layer is formed of a conduction film by forming the conduction film on the insulation film with the opening formed in, polishing the conduction film to expose the insulation film and bury the conduction film in the opening.

16. A method for fabricating a magnetic head according to claim 9, wherein
the insulation film is formed of an inorganic insulation material containing Si and O or an organic insulation material containing C and H.
